(19) United States
(12) Patent Application Publication
(10) Pub. No.: US 2004/0264260 A1
(43) Pub. Date: Dec. 30, 2004

(54) Semiconductor memory device

(75) Inventor: Takashi Kono, Hyogo (JP)

Correspondence Address: McDermott, Will & Emery, 600 13th Street, N.W., Washington, DC, 20005-3096, US

(73) Assignee: RENESAS TECHNOLOGY CORP

(21) Appl. No.: 10/878,227

(22) Filed: Jun. 29, 2004

(30) Foreign Application Priority Data
Jun. 30, 2003 (JP) 2003-187343(P)

(51) Int. Cl. G11C 5/00

(52) U.S. Cl. 365/189.07

(57) ABSTRACT

A data bus of a single-end structure is arranged commonly to a plurality of banks, and a reference data bus transferring reference data providing a criterion of logical level determination of transfer data is arranged corresponding to each bank. For generating a reference potential, a Vref generating circuit is arranged neighboring and corresponding to a DQ circuit band performing input/output of data such that the reference potential required in a data write operation and a data read operation is transmitted to each reference data bus in a concentrated fashion. A semiconductor memory device thus formed transfers data fast with low current consumption without increasing an interconnection layout area.

### BACKGROUND OF THE INVENTION

1. Field of the Invention

The present invention relates to a semiconductor memory device, and particularly to a structure of a portion related to internal data transfer in a semiconductor memory device provided with an internal bus transferring data of a width of multiple bits.

2. Description of the Background Art

In recent years, operation speeds of information processing devices such as a CPU (Central Processing Unit) and others have remarkably increased, and accordingly there has been a strong demand for speeding up of cache memories and main storage memories. For example, an SDRAM (Synchronous Dynamic Random Access Memory) capable of fast data input/output synchronously with an external clock signal is in the mainstream of the market of DRAMs (Dynamic Random Access Memories) that are generally employed as main storage memories. Among such SDRAMs, DDR (Double Data Rate) SDRAMs can perform fast input/output of data in synchronization with both rising and falling edges of an external clock signal, and are increasingly put into practical use.

Specifications of the DDR-SDRAMs are developed by the standardization organization called JEDEC (Joint Electron Device Engineering Council), and there are two kinds of specifications called “DDR-I” and “DDR-II”. These specifications of two kinds have such a common feature that data of N-bits/cycle (N≧2) per I/O pin (DQ) is transferred internally with a memory array. In a data read operation, the number, N, of data read by one memory array access operation for one I/O pin is equal to two (N=2) in the DDR-I specification, and is equal to four (N=4) in the DDR-II specification. This operation is referred to as “N-bit prefetch”. Data of N bits read in parallel from a selected block in the memory array, is P/S (parallel to serial) converted in an I/O circuit band (referred to as a “DQ circuit band” hereinafter), and is appropriately ordered in accordance with an address signal. Then, the data are externally output in synchronization with each of the rising and falling edges of the external clock signal.

In the data write operation, the DQ circuit band performs serial to parallel conversion on the data of N bits externally applied over N/2 cycles, to produce parallel data, and the parallel data bits are transferred to selected blocks in corresponding memory arrays.

For achieving fast data transfer and low power consumption, internal data is transferred in the form of a small amplitude signal. Generally, for transferring a small amplitude signal, data must be formed into complementary signals so as to ensure an effective signal amplitude. Therefore, two signal lines are required for each bit of internal data. In the case of data transfer according to the above mentioned N-bit prefetch scheme, if data word structure is M bits, 2·M·N data bus lines are required, resulting in an increased bus interconnection area to increase a chip area.

For reducing an area occupied by the internal bus in such complementary data line structure, a prior art document 1 (Japanese Patent Laying-Open No. 4-132073) and a prior art document 2 (Japanese Patent Laying-Open No. 2001-52480) disclose a structure, in which an internal data bus is formed into a single-end structure so as to transmit internal data of one bit through one internal data line.

According to the structure disclosed in the prior art document 1, the internal data line is formed into the single-end structure, and a data read circuit compares a potential on each internal data line with a reference voltage to read out internal data.

According to the structure disclosed in the prior art reference 2, a global data bus transferring data between a memory array and a data I/O interface circuit is formed into a single-end structure. Sender/receiver circuits are arranged on opposite ends of the global data bus line, and a reference voltage line transmitting a reference voltage as well as a data strobe line transmitting a data strobe signal are arranged in parallel with the global data bus. Drivers are arranged on opposite ends of the reference voltage line and the data strobe signal line, respectively. The global data line, reference voltage line and data strobe signal line are pulled up to a power supply voltage level via clamp resistances.

In transferring data, each data line of a global data bus is driven on a sender side according to data to be sent (transmission data), and at the same time, the reference voltage line is driven. The driver of the reference voltage line is smaller in driving capability than the other drivers of the global data lines and data strobe line, and the reference voltage line driver is activated before the data transfer. Thus, the reference voltage line is kept at a voltage level determined by a current driving capability of the reference voltage line driver a resistance value of the clamping pull-up resistance. A data strobe signal line is driven according to the transfer data is driven on the sender side at a predetermined timing, and the data strobe signal is transferred. On a receiver side, a signal voltage on the data strobe signal line is compared with a voltage on the reference voltage line, and reception data is produced in accordance with the result of comparison.

According to the structure disclosed in the prior art document 1, the internal data line is precharged to the same voltage level as the bit line precharge voltage. The reference voltage generating circuit generates a voltage used both in the operation of precharging the internal data and in the operation of reading data, and therefore continuously operates to generate the reference voltage at a fixed voltage level. In the arrangement of the prior art document, the voltage level of the reference voltage line is fixed, and therefore, data reading can not be started before the voltage level of the data line exceeds the fixed level of the reference voltage, and thus a cycle time can not be reduced.

According to the arrangement of the prior art document 1, the internal data line is driven, in the data read operation, to such a CMOS level that an H level (logical high level) of data is a power supply voltage level and an L level (logical low level) is a ground voltage level, and no consideration is paid on a configuration for driving the internal data line in a small amplitude.

In addition, the prior art document 1 does not pay any consideration on a configuration and an arrangement -position of the reference voltage generating circuit, and further on a bus structure and arrangement of the reference voltage line in a multi-bank structure. Accordingly, it is difficult to apply the structure taught in the prior art document 1 to the structure for operating fast to transfer a data signal in a small amplitude, as in the DDR SDRAM or the like.

According to the structure of the prior art document 2, the global data line, strobe signal line and reference voltage line are clamped by the clamp resistances, the reference voltage line is set to the voltage level depending on the resistance value of the clamp resistance and the current drive capability of the drive transistor in accordance with an I/O enable signal, and then the voltages on the reference voltage line and the strobe signal line are compared with each other according to a strobe timing signal in each data transfer operation so that a data strobe signal is produced. According to this data strobe signal, a signal on the global data line is compared with the reference voltage to strobe the data. A transistor driving the global data line is made to have a doubled current driving capability of transistor driving the reference voltage line so that the voltage on the global data line attain high and low levels with the voltage on the reference voltage line being the center. However, resistance values of the clamp resistances vary for the global data line and the reference voltage line, a margin of the data with respect to the reference voltage lowers, and it becomes difficult to determine the logical level of the data.

The prior art document 2 discloses that the reference voltage generating circuits are arranged in the banks and the I/O interface circuit, respectively, and the reference voltage generating circuits are activated on the data sender side. In this arrangement, the reference voltage generating circuits are distributed over and arranged in the banks and the I/O interface circuit, and occupy a large area. Further, the prior art document 2 has not explicitly discloses bus connection and arrangement of the reference voltage generating circuits in the multi-bank structure. Specifically, the prior art reference 2 fails to show whether the I/O interface circuits and the banks are arranged in a one-to-one correspondence or in a one-to-multiple correspondence.

Further, in the prior art document 2, strobe timing of the received data is produced based on comparison with the reference voltage, and therefore a dedicated strobe signal line is required, separately from the data line for data transfer and the reference voltage line, resulting in an increased interconnection area of signal lines. Furthermore, a circuit of driving the strobe signal line is required so that a chip occupation area for the circuitry for data transfer increases.

### SUMMARY OF THE INVENTION

An object of the invention is to provide a semiconductor memory device of a multi-bank structure allowing accurate transfer of a small amplitude signal with a small occupation area.

A semiconductor memory device according to the invention includes a plurality of memory banks each having a plurality of memory cells, and each being driven to a selected state independently of others; and a data bus of a multi-bit width arranged commonly to the banks for transferring data. This data bus has a single-end structure having one data line per one bit of data.

The semiconductor memory device according to the invention further includes a plurality of reference data lines arranged corresponding to the banks; I/O circuitry for transmitting external data; a plurality of reference potential generating circuits concentratedly arranged corresponding to the I/O circuitry, and driving, in a data access operation, at least the reference data line for a selected bank to produce a reference potential providing a criterion for determining high and low levels of a logical level of the data; and receiver circuitry for comparing, in the data access, each of bits of the data bus with a potential of a corresponding reference data line to produce data corresponding to the logical level of each of the bits.

By concentratedly arranging the reference voltage generating circuits corresponding to the input/output circuits of the I/O circuitry, the circuits of the same pattern can be efficiently arranged, and accordingly the occupation area of the reference voltage generation circuits as a whole can be reduced.

By arranging the reference potential generating circuits concentratedly and corresponding to the I/O circuitry, variations in characteristics possibly produced during the manufacturing steps of the reference voltage generating circuits can be made averaged and the reference voltages of uniform characteristics can be produced for the respective banks, to reduce the variations in operating margin among the banks.

Further, the reference potential generating circuits are arranged corresponding to the I/O circuit, or near the I/O circuitry, and can transfer the reference voltages to the corresponding banks in synchronization with the data transfer from the I/O circuitry to the receiver circuitry, so that transfer characteristics of the reference voltage and transfer data can be made the same, and the receiver circuitry can have an improved operating margin.

Since the reference data lines are arranged corresponding to the banks, respectively, a load (parasitic capacitance) of each reference data line can be reduced, and it becomes possible to reduce power consumption in driving the reference data line.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows a whole structure of a semiconductor memory device according to the invention.

FIG. 2 schematically shows a chip layout of the semiconductor memory device according to the first embodiment of the invention.

FIG. 3 schematically shows a structure of a column-repetition band shown in FIG. 2.

FIG. 4A shows an example of a configuration of a read data driver shown in FIG. 3, and FIG. 4B schematically shows a configuration of a read reference driver shown in FIG. 3.

FIG. 5 shows an example of a configuration of a write amplifier shown in FIG. 3.

FIG. 6 shows a configuration of a portion generating a write amplifier activating signal shown in FIG. 5.

FIG. 7 shows an example of a configuration of a portion generating a write mode instructing signal shown in FIG. 5.

FIG. 8 schematically shows a configuration of a DQ circuit band shown in FIG. 2.

FIG. 9A shows an example of a configuration of a read amplifier shown in FIG. 8, and FIG. 9B shows an example of a configuration of a portion generating various control signals shown in FIG. 9A.

FIG. 10 shows an example of a configuration of a write data driver shown in FIG. 8.

FIG. 11 shows an example of a configuration of a write reference driver shown in FIG. 8.

FIG. 12 is a signal waveform diagram representing an internal read data transfer operation in a data read mode according to the first embodiment of the invention.

FIG. 13 is a signal waveform diagram representing an internal write data transfer operation in a data write mode according to the first embodiment of the invention.

FIG. 14 shows a configuration of a read reference driver according to a modification of the first embodiment of the invention.

FIG. 15 shows a configuration of a write reference driver according to the modification of the first embodiment of the invention.

FIG. 16 schematically shows an interconnection layout according to a second modification of the first embodiment of the invention.

FIG. 17 schematically shows a configuration of a reference data line according to a third modification of the first embodiment of the invention.

FIG. 18 schematically shows a chip layout of a semiconductor memory device according to a second embodiment of the invention.

FIG. 19 schematically shows a configuration of a column-repetition band shown in FIG. 18.

FIG. 20 schematically shows a configuration of a DQ circuit band shown in FIG. 18.

FIG. 21 schematically shows a structure of a Vref generating circuit shown in FIG. 18.

FIG. 22 represents operation waveforms in internal data transfer in a data read mode according to the second embodiment of the invention.

FIG. 23 represents operation waveforms in write data transfer in a data write mode according to the second embodiment of the invention.

FIG. 24 shows an example of a configuration of an equalizer shown in FIG. 1.

FIG. 25 schematically shows a structure of a Vref generating circuit of a modification of the second embodiment of the invention.

FIG. 26 shows an example of a configuration of a buffer circuit shown in FIG. 25.

### DESCRIPTION OF THE PREFERRED EMBODIMENTS

[Whole Structure]

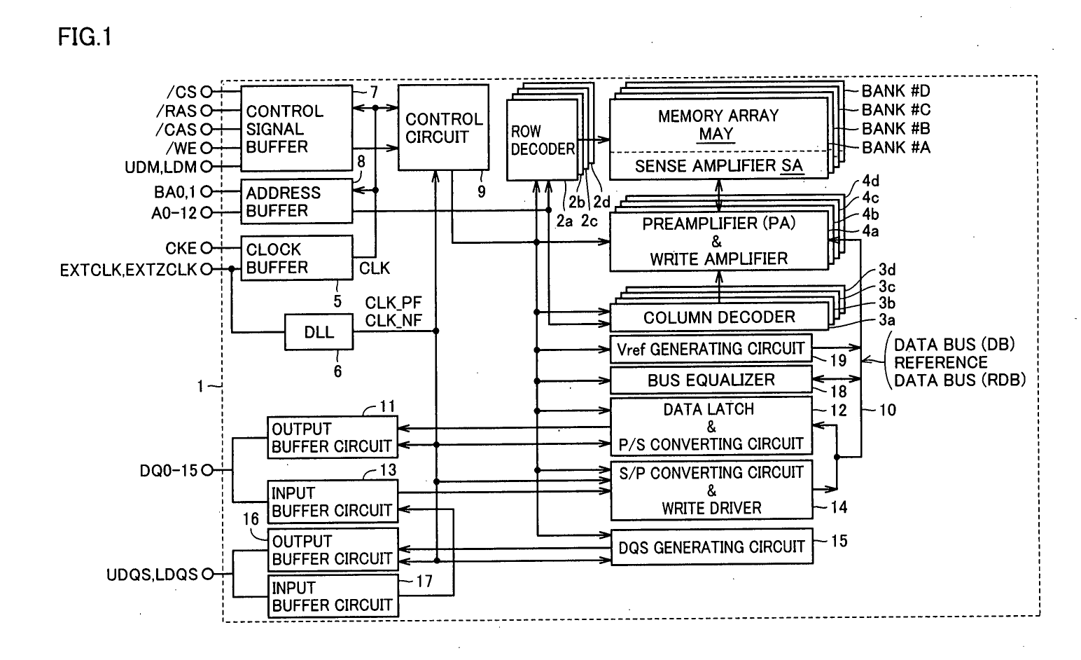

FIG. 1 schematically shows a construction of a whole semiconductor memory device according to the invention. A semiconductor memory device 1 shown in FIG. 1 is an SDRAM transferring data in a DDR mode. Semiconductor memory device 1 shown in FIG. 1 includes a plurality of banks #A-#D. These banks #A-#D can be driven to a selected state independently of each other. Each of banks #A-#D includes a memory array MAY having a plurality of memory cells arranged in rows and columns, and a sense amplifier SA for sensing, amplifying and latching data of the memory cells in a selected row of memory array MAY when made active. Sense amplifier SA includes sense amplifier circuits arranged corresponding to the columns in a corresponding memory array MAY and each for sensing, amplifying and latching data of the memory cell in a corresponding column when made active.

Corresponding to the respective banks #A-#D, there are provided row decoders 2a-2d each for driving a row in a corresponding memory array MAY to the selected state in accordance with received row address, column decoders 3a-3d each for producing a column select signal selecting the column in a corresponding memory arrays MAY in accordance with received column address signal, and internal read/write circuits 4a-4d each for performing read/write of data from and into the selected memory cells in the memory arrays MAY of the corresponding bank. Each of internal read/write circuits 4a-4d includes a preamplifier (PA), made active in a data read operation, for producing internal read data by amplifying the memory cell data read from the corresponding memory array MAY, and a write amplifier, made active in a data write operation, for amplifying and transferring received internal write data and to the selected memory cell in the corresponding memory array.

These internal read/write circuits 4a-4d are commonly coupled to a main data bus 10. The main data bus, of which specific structure will be described later, includes a data bus DB having a single-end structure and transferring internal data, and a reference data bus RDB for transferring a reference potential used as a criterion of determination of high and low levels of the data transferred on data bus DB. Main data bus 10 transferring the internal data includes reference data bus lines transferring reference potentials, and each of the reference data bus lines is arranged corresponding to a predetermined number of data bus lines. Thus, the number of data lines can be reduced as compared with the data bus in a double-end structure employing complementary data line pair, and an interconnection area of the bus can be reduced.

Semiconductor memory device 1 further includes a clock buffer 5 receiving externally applied complementary clock signals EXTCLK and EXTZCLK, to producing an internal clock signal CLK when a clock enable signal CKE is active, a phase lock loop (DLL) 6 for producing clock signals CLK_PF and CLK_NF of two phases in accordance with external clock signals EXTCLK and EXTZCLK, a control signal buffer 7 taking in externally applied control signals, i.e., a chip select signal /CS, a row address strobe signal /RAS, a column address strobe signal /CAS, a write enable signal /WE, an upper byte data mask signal UDM and a lower byte data mask signal LDM in accordance with clock CLK received from clock buffer 5, to produce internal control signals, an address buffer 8 taking in externally applied bank address signals BA0 and BA1 as well as address signals A0-A12 in synchronization with internal clock signal CLK received from clock buffer 5, to produce internal address signals, and a control circuit 9 for producing various internal operation control signals in accordance with control signals applied from control signal buffer 7 in synchronization with internal clock signal CLK received from clock buffer 5 and internal clock signals CLK_PF and CLK_NF received from phase lock loop 6.

Control circuit 9 operates based on internal clock signal CLK, and produces operation timing control signals to row decoders 2a-2d, column decoders 3a-3d and internal read/write circuits 4a-4d in accordance with the control signals generated from control signal buffer 7.

Clock signals CLK_PF and CLK_NF of two phases generated from phase lock loop 6 are used for parallel to serial conversion and serial to parallel conversion of the internal data as well as external transfer of data from the device in a DDR-mode operation.

In the semiconductor memory device shown in FIG. 1, control circuit 9 is not supplied with a bank address signal specifying the bank. Control circuit 9 applies main control signals to row decoders 2a-2d, column decoders 3a-3d and internal read/write circuits 4a-4d, and selection or non-selection of the decoders and the read/write circuits is determined based on the bank address signal. In the selected bank, the local control signals are produced according to the control signals applied from control circuit 9, and the operations of selecting the row or column of the memory cells as well as the data read/write operation are executed.

Semiconductor memory device 1 further includes a read transfer circuit 12 for latching the data transferred through main data bus 10 for conversion into serial data in the data read operation, a write transfer circuit 14 for converting the data applied externally and serially to parallel data for transference onto main data bus 10 in the data write operation, a DQS generating circuit 15 for generating a data strobe signal DQS under the control of control circuit 9 in the data read operation, an output buffer circuit 11 for successively outputting the data transferred from read transfer circuit 12 in accordance with clock signals CLK_PF and CLK_NF generated from phase lock loop 6, an input buffer circuit 13 receiving externally applied data DQ0-DQ15 for transference to write transfer circuit 14 in the data write operation, an output buffer circuit 16 for outputting, in the data read operation, data strobe signal DQS applied from DQS generating circuit 15 in accordance with clock signals CLK_NF and CLK_PF, and to produce upper-byte and lower-byte data strobe signals UDQS and LDQS, and an input buffer circuit 17 for producing a strobe signal in accordance with externally applied data strobe signals. UDQS and LDQS and applying the produced strobe signal to input buffer circuit 13.

Read transfer circuit 12 includes a parallel-serial converting circuit (P/S converting circuit) for converting data applied in parallel from main data bus 10 to serial data for outputting. This parallel-serial converting circuit performs the conversion according to clock signals CLK_PF and CLK_NF. Similarly, write transfer circuit 14 includes a S/P converting circuit (S/P converting circuit) for converting the serial data to the parallel data, and converts the data applied serially from input buffer circuit 13 to parallel data in accordance with clock signals CLK_PF and CLK_NF.

Data strobe signals UDQS and LDQS provided from output buffer circuit 16 are used for determining data sampling timing when the receiver side receives data DQ0-DQ15 from semiconductor memory device 1. Data strobe signal sent from input buffer circuit 17 is transferred from a device on the sender side of data DQ0-DQ15, and determines the timing of data strobing in input buffer circuit 13.

Semiconductor memory device 1 further includes a bus equalizer 18 for precharging each bus line in main data bus 10 to a predetermined potential, and a Vref generating circuit 19 for driving the reference data bus RDB included in main data bus 10, and generates a reference potential Vref. Vref generating circuit 19 dynamically drives reference data bus RDB to change the potential on the bus line of reference data bus RDB at the same timing as the timing of the data transfer on data bus DB. Thus, a timing relationship between the reference potential and the transfer data bits is established reliably.

By utilizing reference potential Vref supplied from Vref generating circuit 19 as the determination criterion of high/low level of the data bits transferred from data bus DB, the data can be transferred effectively in the form of complementary data via the bus of the single-end structure, so that the number of bus lines in main data bus 10 can be reduced without impairing the transference characteristics of the small-amplitude signal.

### First Embodiment

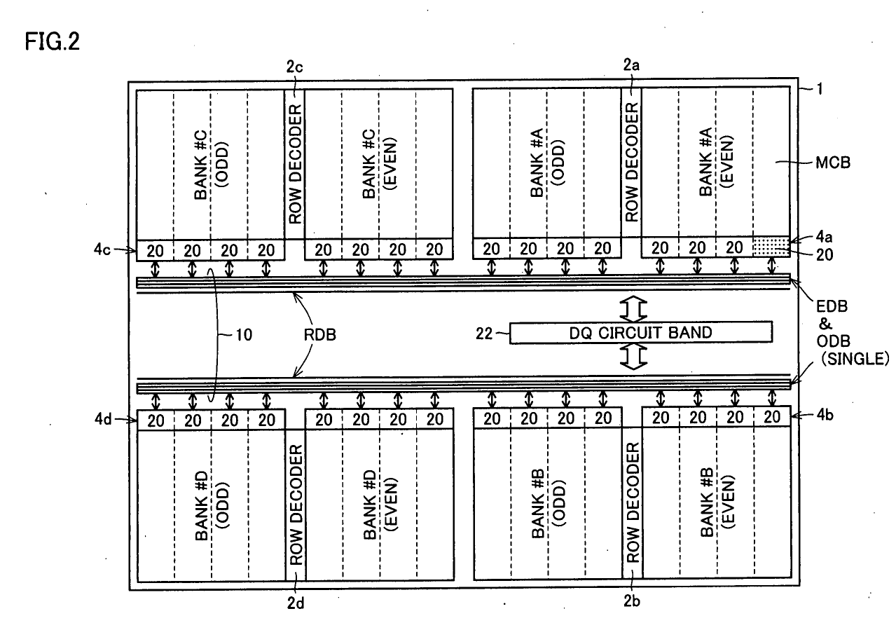

FIG. 2 schematically shows a chip layout of the semiconductor memory device according to a first embodiment of the invention. In FIG. 2, semiconductor memory device 1 includes banks #A-#D arranged distributedly. Banks #A and #C are arranged adjacently to each other, and banks #B and #D are arranged adjacently to each other. Each of banks #A-#D performs internal data transfer in a 2-bit prefetch scheme, so that the memory array is divided into an even-number plane EVEN and an odd-number plane ODD. Even-number plane EVEN corresponds to least significant bit A0 of the column address being 0 (A0=0), and odd-number plane ODD corresponds to least significant bit A0 of the column address being 1 (A0=1). Ordering of the prefetched 2-bit data is effected by using least significant bit A0 of the column address bit, and therefore, least significant bit A0 of the column address is not concerned in the column selection in each of banks #A-#D. Therefore, the memory cell of one bit is selected per one DQ (I/O data bit) from each of even- and odd-number planes EVEN and ODD.

Each of even- and odd-number planes EVEN and ODD is divided into array column blocks MCB each corresponding to the DQs of the predetermined number of bits. In an example of the structure shown in FIG. 2, array column blocks MCB correspond to four DQs.

Column-repetition bands 20 are arranged corresponding to array column blocks MCB, respectively. Column-repetition band 20 includes preamplifiers and write amplifiers corresponding in number to the bits of an internal data bus (global data bus GIO) in the corresponding array column block.

Main data bus (internal bus) 10 is arranged commonly to banks #A-#D. In the selected bank, data is simultaneously read from both even- and odd-number planes EVEN and ODD. To this end, main data bus 10 includes an even-number plane data bus EDB transferring the data read from the even-number plane and an odd-number plane data bus ODB corresponding to odd-number plane ODD. In the first embodiment, each of data buses EDB and ODB is formed into a single-end structure, and transfers one data bit with one data line.

In main data bus 10, reference data buses RDB are provided corresponding to data buses EDB and ODB, for transferring reference potentials, respectively. Reference data bus RDB provides a potential serving as the criterion for determining high/low levels of an internally transferred small-amplitude data signal. Main data bus 10 is coupled to DQ circuit band 22, and transfers the internal data between DQ circuit band 22 and even-and odd-number planes EVEN and ODD in a selected bank. DQ circuit band 22 includes output buffer circuits 11 and 16, input buffer circuits 13 and 17, read transfer circuit 12, write transfer circuit 14 and DQS generating circuit 15 shown in FIG. 1.

In the data transfer operation, each of data buses EDB and ODB transfers data of one bit by one bus line. However, reference data bus RDB transmits the reference potential, and accordingly the internal small-amplitude data is effectively transferred in the form of the complementary data signals.

It can be considered that no significant difference is present in data amplitude between the H- and L-level data on even- and odd-number plane data buses EDB and ODB in neighboring column-repetition bands 20. Therefore, the reference data line of reference data bus RDB can be shared by a plurality of data lines. For example, one reference data line RDB is arranged for the four data lines of even- or odd-number plane data bus EDB or ODB. In this case, the total number of lines of internal buses is equal to (M·N+M·N/4=(5/4)·M·N), in the case when a word structure is M bits and an N-bit prefetch scheme is utilized. Therefore, as compared with the complementary data line pair (double-end structure), the number of required data lines can be reduced to 5/8 times so that the interconnection area of main data bus 10 can be reduced.

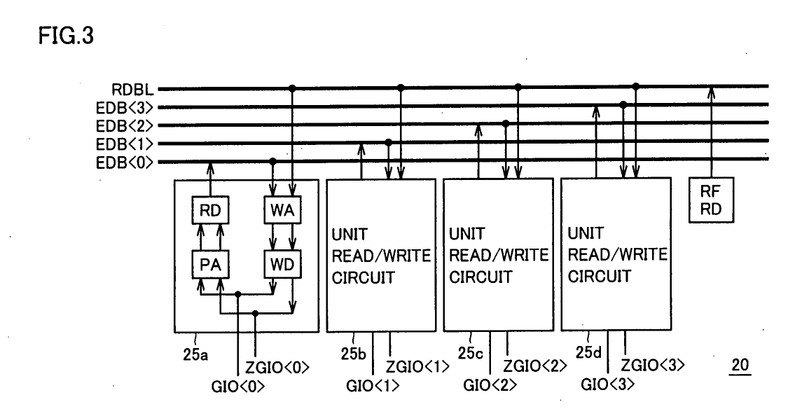

FIG. 3 schematically shows the construction of column-repetition band 20 shown in FIG. 2. In FIG. 3, column-repetition band 20 is arranged for the even-number plane, and transfers the data of 4 bits between corresponding array column block MCB and the even-number plane data lines EDB<3:0>.

In FIG. 3, column-repetition band 20 includes unit read/write circuits 25a-25d arranged corresponding to global data line pairs GIO<0> and ZGI0<0>-GIO<3> and ZGIO<3> included in array column block MCB shown in FIG. 2, respectively, and a read reference driver RFRD activated when data is read out from a corresponding array column block to generate the reference potential.

Unit read/write circuits 25a-25d have the same structure, and therefore, FIG. 3 shows the specific structure of only unit read/write circuit 25a. Unit read/write circuit 25a includes a preamplifier PA made active in data read out to amplify the data on global data lines GIO<0> and ZGIO<0>, a read data driver RD for driving even-number plane data line EDB<0> in accordance with the data amplified by preamplifier PA, a write amplifier WA made active in data writing to produce complementary data in accordance with a signal on reference data line RDBL and a signal on even-number plane data line EDB<0>, and a write data driver WD for driving global data lines GIO<0> and ZGIO<0> in accordance with complementary output signals of write amplifier WA.

Unit read/write circuit 25b drives even-number plane data line EDB<1> in accordance with the memory cell data read onto global data lines GIO<1> and ZGIO<1> in the data read mode, and, in the data write mode, to produce complementary data in accordance with the signals on reference data line RDBL and even-number plane data line EDB<1>, for driving global data lines GIO<1> and ZGIO<1>.

Unit read/write circuit 25c drives even-number plane data line EDB<2> in accordance with the memory cell data read onto global data lines GIO<2> and ZGIO<2> in the data reading, and in the data writing, produces complementary data in accordance with the signals on reference data line RDBL and even-number plane data line EDB<2>, for driving global data lines GIO<2> and ZGIO<2>.

Unit read/write circuit 25d drives even-number plane data line EDB<3> in accordance with complementary signals on global data lines GIO<3> and ZGIO<3> in the data reading, and in the data write operation, produces complementary data in accordance with the signals on reference data line RDBL and even-number plane data line EDB<3>, for driving global data lines GIO<3> and ZGIO<3>.

Each of even-number plane data lines EDB<0>-EDB<3> is a single data line, but equivalently transfers complementary signals through the use of the signal on reference data line RDBL.

Global data lines GIO<0> and ZGIO<0>-GIO<3> and ZGIO<3> extend along the column direction in corresponding array column block MCB, and are coupled to selected memory cells (sense amplifier circuits) via local data lines (not shown). The memory array can have any construction.

Read reference driver RFRD is activated to drive reference data line RDBL when data is to be read from column-repetition band 20. In the data writing, each of unit read/write circuits 25a-25d determines the logical level of the write data in accordance with the reference potential that is transmitted from the reference potential generating circuit included in DQ circuit band 22 (see FIG. 2) onto reference data line RDBL, and produces the complementary internal write data.

Column-repetition band 20 shown in FIG. 3 is arranged corresponding to the even-number plane data line. Each column-repetition band 20 corresponding to odd-number plane data bus ODB has the substantially same structure.

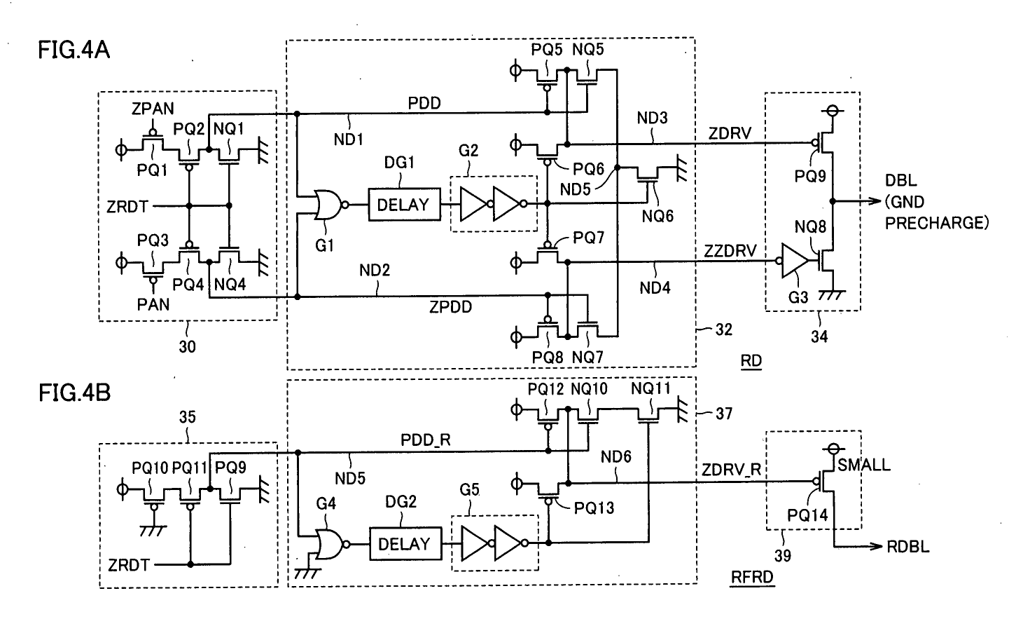

FIG. 4A shows an example of the configuration of read data driver RD included in each of unit read/write circuits 25a-25d shown in FIG. 3. In FIG. 4A, read data driver RD includes a transfer stage 30 for transferring output signals PAN and ZPAN of the preamplifier (PA) in accordance with transfer control signal ZRDT, a one-shot pulse generating stage 32 for producing complementary signals ZDRV and ZZDRV in the a one-shot pulse form in accordance with complementary signals PDD and ZPDD transferred from transfer stage 30, and a drive stage 34 for driving data line DBL in accordance with output signals ZDRV and ZZDRV of one-shot pulse generating stage 32.

In the following description, the reference symbol “DBL” is used for generally indicating the data line, and the reference symbol “RDBL” is used for generally indicating the reference data line. Reference symbol “DB<i>” indicates the data line corresponding to data bit DQ<i>.

Transfer stage 30 includes a P-channel MOS transistor (insulated gate field-effect transistor) PQ1 having a source connected to a power supply node and a gate receiving the output signal ZPAN of the preamplifier (PA), a P-channel MOS transistor PQ2 coupling a drain of MOS transistor PQ1 to a node ND1 in accordance with transfer control signal ZRDT, an N-channel MOS transistor NQ1 rendered conductive complementarily to MOS transistor PQ2 in accordance with transfer control signal ZRDT, and maintaining node ND1 at a ground voltage level when made conductive, a P-channel MOS transistor PQ3 having a source connected to the power supply node and a gate receives output signal PAN of the preamplifier, a P-channel MOS transistor PQ4 coupling a drain node of MOS transistor PQ3 to a node ND2 in accordance with transfer control signal ZRDT, and an N-channel MOS transistor NQ4 made conductive complementarily to MOS transistor PQ4 in accordance with transfer control signal ZRDT, and maintaining node ND2 at the ground voltage level when made conductive.

In a precharged state, output signals PAN and ZPAN of the preamplifier are at the H level (power supply voltage level), and MOS transistors PQ1 and PQ3 are in an off state. In this precharged state, transfer control signal ZRDT is at the H level, MOS transistors PQ2 and PQ4 are in the off state, MOS transistors NQ1 and NQ4 are in the on state, and nodes ND1 and ND2 are kept at the ground voltage level.

In the data read operation, when output signals PAN and ZPAN of the preamplifier change to develop a sufficient difference between them, transfer control signal ZRDT is made active so that MOS transistors NQ1 and NQ4 turn non-conductive, and MOS transistors PQ2 and PQ4 turn conductive. MOS transistors PQ1 and PQ3 are made conductive to transmit the power supply voltage when output signals ZPAN and PAN of the corresponding preamplifier are at the L-level. Therefore, when output signal ZPAN of the preamplifier is at the L level, node ND1 is supplied with the power supply voltage, and the signal PDD on node ND1 rises from the ground voltage level. When output signal ZPAN of the preamplifier is at the H level, MOS transistor PQ1 is conductive, and the signal PDD on node ND1 is maintained at the ground voltage level. Similarly, the signal ZPDD on node ND2 rises its voltage level when output signal PAN of the preamplifier is at the L level, while is kept at the ground level when output signal PAN is at the H level.

One-shot pulse generating stage 32 includes a NOR gate G1 receiving the signals PDD and ZPDD on nodes ND1 and ND2, a delay circuit DG1 for delaying an output signal of NOR gate G1, a buffer circuit G2 for buffering an output signal of delay circuit DG1, a P-channel MOS transistor PQ5 transmitting the power supply voltage to a node ND3 in accordance with signal PDD on node ND1, an N-channel MOS transistor NQ5 coupling node ND3 to a MOS transistor NQ6 in accordance with the signal PDD on node ND1, a P-channel MOS transistor PQ8 transmitting the power supply voltage onto a node ND4 in accordance with the signal ZPDD on node ND2, an N-channel MOS transistor NQ7 coupling node ND4 to a node ND5 in accordance with signal ZPDD on node ND2, P-channel MOS transistors PQ6 and PQ7 made conductive when an output signal of buffer circuit G2 is at the L level, to transmit the power supply voltage to nodes ND3 and ND4, and an N-channel MOS transistor NQ6 made conductive when an output signal of buffer circuit G2 is at the H level, to set node ND5 to the ground voltage level.

In the precharged state, both the signals PDD and ZPDD on nodes ND1 and ND2 are at the L level, and accordingly the output signal of NOR gate G1 is at the H level. The output signal of delay circuit DG1 is at the L level so that the output signal of buffer circuit G2 is at the L level. Therefore, MOS transistors PQ6 and PQ7 are conductive, and MOS transistor NQ5 is non-conductive, so that MOS transistors PQ6 and PQ7 precharge the nodes ND3 and ND4 to the power supply voltage level, respectively.

Since signals PDD and ZPDD are at the L-level, MOS transistors PQ5 and PQ8 are on, and transmit the power supply voltage to nodes ND3 and ND4, respectively. In the precharged state, therefore, both output signals ZDRV and ZZDRV of one-shot pulse generating stage 32 are at the H level.

When the data reading starts and transfer stage 30 operates, the voltage levels of signals PDD and ZPDD on nodes ND1 and ND2 change, one of which rises. It is now assumed that the voltage level of signal PDD rises. When the signal PDD on node ND1 attains the H level, the output signal of NOR gate G1 attains the L level. At this time point, the output signal of delay circuit DG1 is still at the H level, and therefore the output signal of buffer circuit G2 is at the H level. Accordingly, MOS transistors PQ6 and PQ7 are in an off state, and MOS transistor NQ6 is in an on state. Accordingly, when the signal PDD attains the H level, MOS transistors NQ5 and NQ6 drive the node ND3 to the ground voltage level, and thus drive the signal ZDRV on node ND3 to the L level. The signal ZPDD is kept at the L level. Accordingly, MOS transistor PQ8 is conductive, and MOS transistor NQ7 is non-conductive, so that node ND4 is isolated from node ND5, and the signal ZZDRV on node ND4 maintains the H level.

When a delay time provided by delay circuit DG1 elapses, the output signal of buffer circuit G2 attains the L level in accordance with the output signal of NOR gate G1, MOS transistor NQ6 is turned off, and MOS transistors PQ6 and PQ7 are turned on. Responsively, MOS transistor PQ6 charges node ND3 to drive the signal ZDRV to the H level. Thus, one-shot pulse generating stage 32 changes the signals ZDRV and ZZDRV to the state corresponding to output signals PAN and ZPAN of the preamplifier during the period provided by delay circuit DG1.

When the data read cycle completes, the signals PDD and ZPDD on nodes ND1 and ND2 are driven to the L level so that MOS transistors PQ5 and PQ8 charge the nodes ND3 and ND4 to the power supply voltage level, respectively. When both the signals PDD and ZPDD attain the L level, the output signal of NOR gate G1 attains the H level. When the delay time of delay circuit DG1 elapses, the output signal of buffer circuit G2 attains the H level. Accordingly, MOS transistors PQ6 and PQ7 are turned off, and MOS transistor NQ6 is turned on. At this time point, MOS transistors NQ5 and NQ7 are already turned off, and nodes ND3 and ND4 are isolated from node ND5. Thus, MOS transistors PQ5 and PQ8 reliably maintain the nodes ND3 and ND4 at the power supply voltage level, respectively.

Drive stage 34 has a P-channel MOS transistor PQ9 connected between the power supply node and data line DBL and having a gate receiving output signal ZDRV of one-shot pulse generating stage 32, an inverter G3 receiving complementary output signal ZZDRV of one-shot pulse generating stage 32, and an N-channel MOS transistor NQ8 connected between data line DBL and the ground node and having a gate receiving an output signal of inverter G3.

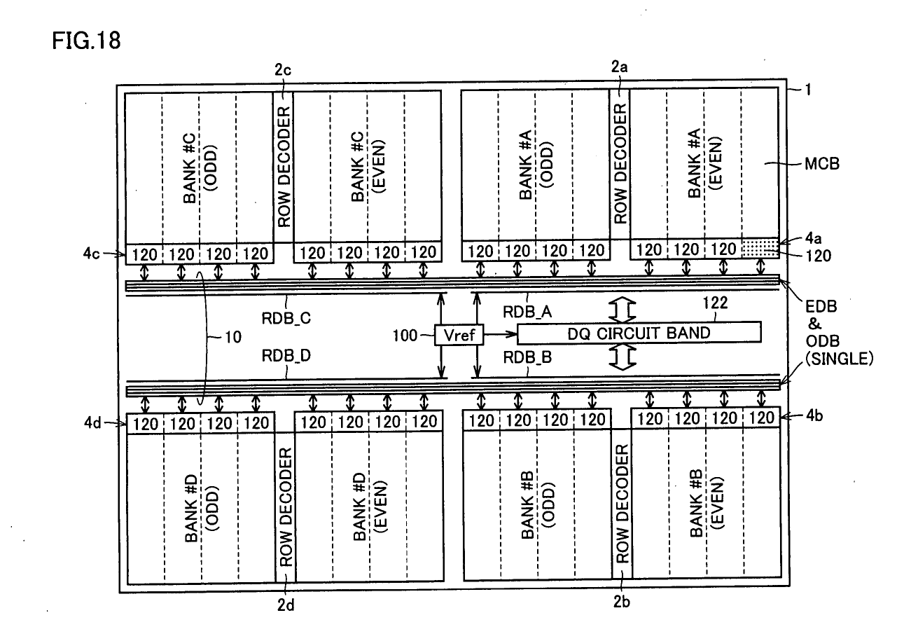

Signals ZDRV and ZZDRV generated from one-shot pulse generating stage 32 are at the H level during the precharged state. Therefore, in drive stage 34, MOS transistors PQ9 and NQ8 are both in an off state during the precharged state. Data line DBL precharged by a not-shown precharging element (bus equalizer 18 in FIG. 18), maintains the ground voltage level during the precharged state.

In the data read operation, one of signals ZDRV and ZZDRV attains the H level, and the other attains the L level. Therefore, one of MOS transistors PQ9 and NQ8 is turned on, and the other is kept off. When signal ZDRV is at the L level, MOS transistor PQ9 charges data line DBL for a predetermined period to raise its voltage level. When signal ZDRV is at the H level, data line DBL is maintained at the precharged ground voltage level. The duration period for which drive stage 34 drives data line DBL, depends on the one-shot pulse generating time period (i.e., delay time of delay circuit DG1) of one-shot pulse generating stage 32. By driving data line DBL in a short period of time, the data transfer period of time is reduced, fast data transfer is achieved, and in addition, an amplitude of the bus line is reduced.

FIG. 4B shows a configuration of read reference driver RFRD shown in FIG. 3. In FIG. 4B, read reference driver RFRD includes a transfer stage 35 for transferring reference data to node ND5 in accordance with transfer control signal ZRDT, a one-shot pulse generating stage 37 for producing a drive signal ZDRV_R of one shot in accordance with the reference data transferred from transfer stage 35, and a drive stage. 39 for driving reference data line RDBL in accordance with output signal ZDRV_R of one-shot pulse generating stage 37.

Transfer stage 35 includes a P-channel MOS transistor PQ10 having a source connected to the power supply node and a gate connected to the ground node, a P-channel MOS transistor PQ11 connected between a drain of MOS transistor Q10 and node ND5 and having a gate receiving transfer control signal ZRDT, and an N-channel MOS transistor NQ9 connected between node ND5 and the ground node and having a gate receiving transfer control signal ZRDT.

Transfer stage 35 has the same configuration as one of the complementary signal transfer paths in transfer stage 30 included in read data driver RD shown in FIG. 4A. Thus, transfer stage 35 of read reference driver RFRD has the same configuration as the path receiving the output signal of the preamplifier at the L level of transfer stage 30 of read data driver RD. In the precharged state, therefore, node ND5 is precharged by MOS transistor NQ9 to the ground voltage level. In the data transfer operation, node ND5 is supplied with the power supply voltage via MOS transistors PQ10 and PQ11.

One-shot pulse generating stage 37 includes an NOR gate G4 receiving a signal PDD_R on node ND5 and the ground voltage, a delay circuit DG2 delaying the output signal of NOR gate G4, a buffer circuit G5 buffering an output signal of delay circuit DG2, a P-channel MOS transistor PQ12 connected between the power supply node and a node ND6 and having a gate receiving the signal PDD_R on node ND5, N-channel MOS transistors NQ10 and NQ11 connected in series between node ND6 and the ground node, and a P-channel MOS transistor PQ13 connected between the power supply node and node ND6 and having a gate receiving an output signal of buffer circuit G5.

MOS transistor NQ11 receives, on its gate, the output signal of buffer circuit G5, and N-channel MOS transistor NQ10 receives, on its gate, signal PDD_R from node ND5.

One-shot pulse generating stage 37 has the same configuration as one of the signal transfer paths of one-shot pulse generating stage 32 in read data driver RD shown in FIG. 4A. In the precharged state, therefore, signal PDD_R on node ND5 is at the L level. Accordingly, MOS transistor PQ12 is in an on state to precharge node ND6 to the power supply voltage level, while MOS transistor NQ10 is in an off state. In the data transfer operation, signal PDD_R on node ND5 attains the H level in accordance with the power supply voltage transferred from transfer stage 35, and accordingly, NOR gate G4 generates the output signal at the L level. In accordance with signal PDD_R on node ND5, MOS transistor PQ12 is turned off, and MOS transistor NQ10 is turned on, and responsively, node ND6 is coupled to MOS transistor NQ11. At this time point, the output signal of buffer circuit G5 is still at the H level, and MOS transistor NQ11 is in an on state, and accordingly, signal ZDRV_R on node ND6 is driven to the L level. When the delay time of delay circuit DG2 elapses, the output signal of buffer circuit G5 attains the L level, so that MOS transistor NQ11 is turned off, but MOS transistor PQ13 is turned on to drive signal ZDRV_R on node ND6 to the H level.

When the data transfer cycle is completed, signal PDD_R on node ND5 is driven to the L level again. Responsively, MOS transistor PQ12 is turned on and MOS transistor NQIO is turned off. Node ND6 is kept at the power supply voltage level by MOS transistor PQ12. When the delay time of delay circuit DG2 elapses after signal PDD_R on node ND5 falls to the L level, the output signal of buffer circuit G5 attains the H level to prepare for the next cycle.

One-shot pulse generating stage 37 has the same configuration as one-shot pulse generating stage 32 of read data driver RD shown in FIG. 4A, and therefore can produce signal ZDRV_R in a one-shot pulse form in the same operation characteristics when the read data transfer operation is performed.

Drive stage 39 includes a P-channel MOS transistor PQ14 connected between the power supply node and reference data line RDBL and having a gate receiving signal ZDRV_R. Reference data line RDBL is precharged to the ground voltage level, similarly to data line DBL.

A current driving capability of MOS transistor PQ14 is smaller than the current driving capability of MOS transistor PQ9 shown in FIG. 4A. For example, if the load of reference data line RDBL is the same as that of data line DBL, MOS transistor PQ9 is configured to have a doubled size (a ratio of a channel width to a channel length) of MOS transistor PQ14. Thus, the potential change rate of reference data line RDBL can be made half the potential change rate of data line DBL in the data transfer operation, and the potential on reference data line RDBL can be set to a potential level intermediate between the high- and low-levels of data line DBL.

Read reference driver RFRD are made have a configuration the same as that of read data driver RD and reference data line RDBL and data line DBL are made to be driven in accordance with the same timing control signals. Thus, the column-repetition band can transmit the data and the reference data onto data line DBL and reference data line RDBL at the same timing, respectively.

Usually, reference data line RDBL is connected with more write amplifiers than those connected to data line DBL, and the load thereof is larger than that of data line DBL. Therefore, even if the driving power of MOS transistor PQ14 of drive stage 39 of read reference driver RFRD is substantially equal to that of the current driving power of MOS transistor PQ9 of drive stage 34 in read data driver RD, the potential changing rate of reference data line RDBL can be made sufficiently slower than that of data line DBL, and accordingly, the reference data can be accurately transferred. Therefore, a relationship in current driving power between MOS transistor PQ14 in drive stage 39 and MOS transistor PQ9 in drive stage 34 is appropriately determined in accordance with the magnitudes of the loads of data line DBL and reference data line RDBL.

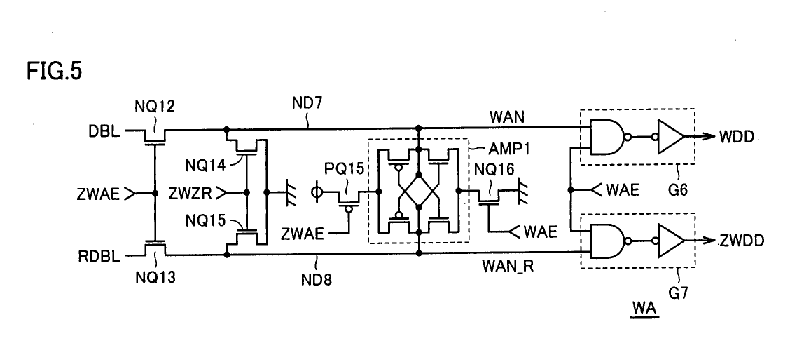

FIG. 5 shows an example of a configuration of write amplifier WA shown in FIG. 3. In FIG. 5, write amplifier WA includes N-channel MOS transistors NQ12 and NQ13 which couple the data line DBL and reference data line RDBL to nodes ND7 and ND8 in response to a complementary write amplifier activating signal ZWAE, respectively, N-channel MOS transistors NQ14 and NQ15 which precharge the nodes ND7 and ND8 to the ground voltage level in response to a write/read instructing signal ZWZR, respectively, a cross-coupled type amplifier AMP1 which differentially amplifies the potentials of nodes ND7 and ND8 when made active, a P-channel MOS transistor PQ15 which supplies the power supply voltage to cross-coupled type amplifier AMP1 in response to activation of a complementary write amplifier activating signal ZWAE, an N-channel MOS transistor NQ16 which supplies the ground voltage to cross-coupled type amplifier AMP1 in response to activation of write amplifier activating signal WAE, an AND gate G6 which receives a signal WAN on node ND7 and write amplifier activating signal WAE and produces write data WDD, and an AND gate G7 which receives write amplifier activating signal WAE and a signal ZWAN on node ND8 and produces complementary write data ZWDD.

MOS transistors NQ12 and NQ13 are turned on to couple data line DBL and reference data line RDBL to nodes ND7 and ND8, respectively, when complementary write amplifier activating signal ZWAE is inactive at the H level. When complementary write amplifier activating signal ZWAE is made active to attain the L level, MOS transistors NQ12 and NQ13 are turned off.

Precharging MOS transistors NQ14 and NQ15 are turned on in response to the inactive state (H level) of write/read instructing signal ZWZR, and are turned off in response to the active state of write/read instructing signal ZWZR. Write/read instructing signal ZWZR is set to the L level in the data write operation. Therefore, precharging of nodes ND7 and ND8 to the ground voltage level stops when the data writing is performed.

Cross-coupled type amplifier AMP1 includes P-channel MOS transistors cross-coupled and supplied, on their common source node, with the power supply voltage via MOS transistor PQ15 when complementary write amplifier activating signal ZWAE is active (L-level). Cross-coupled type amplifier AMP1 further includes N-channel MOS transistors cross-coupled and supplied, on their common source node, with the ground voltage via MOS transistor NQ16 when write amplifier activating signal WAE is active (H level). Therefore, cross-coupled type amplifier AMP1 is made active to amplify differentially the signals WAN and ZWAN on nodes ND7 and ND8 when complementary write amplifier activating signals ZWAE and WAE are made active.

When write amplifier activating signals WAE and ZWAE are active, MOS transistors NQ12 and NQ13 are made non-conductive to isolate nodes ND7 and ND8 from data line DBL and reference data line RDBL, respectively, and cross-coupled type amplifier AMP1 performs the differential amplification operation. By performing the differential amplification while confining electric charges in nodes ND7 and ND8, the signals WAN and ZWAN corresponding to the write data can be produced at high speed while the amplitudes on data line DBL and reference data line RDBL are small.

When write amplifier activating signal WAE is active, AND gates G6 and G7 produce internal write data WDD and ZWDD in accordance with the signals WAN and ZWAN on nodes ND7 and ND8, respectively, onto write driver WD shown in FIG. 3. In the data writing, global data lines GIO and ZGIO are driven in accordance with corresponding internal write data WDD and ZWDD, respectively.

In the precharged state, the signals WAN and ZWAN on nodes ND7 and ND8 are at the L level, and write amplifier activating signal WAE is at the L level, and internal write data WDD and ZWDD are kept at the L level. In the data reading, write amplifier enable signal WAE is inactive, and internal write data WDD and ZWDD are kept at the L level. In this state, therefore, write driver WD shown in FIG. 3 enters an output high-impedance state, and does not adversely affect the reading of the memory cell data.

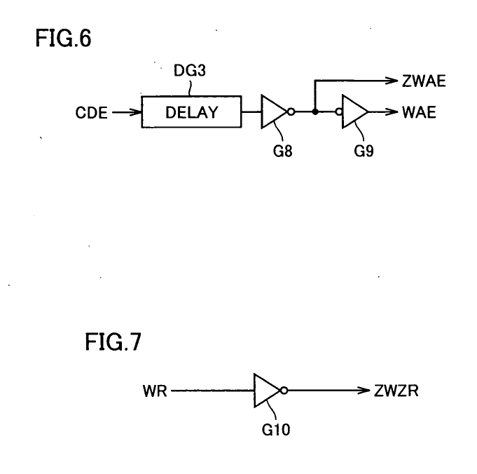

FIG. 6 shows an example of a configuration of a portion generating write amplifier activating signals WAE and ZWAE shown in FIG. 5. Referring to FIG. 6, a write amplifier activating signal generating portion includes a delay circuit DG3 delaying a column decoder enable signal CDE activating the column selection operation, an inverter G8 inverting an output signal of delay circuit DG3 to produce write amplifier activating signal ZWAE, and an inverter G9 inverting an output signal of inverter G8 to produce write amplifier activating signal WAE.

Column decoder enable signal CDE is activated in a selected bank based on a bank address signal and a write operation instructing signal instructing the data writing and applied from control circuit 9 shown in FIG. 1, when a read command or a write command is applied for instructing writing of data. In the memory array, a write column select gate and a read column select gate are arranged separately from each other as a column select gate, and a write column decoder and a read column decoder are correspondingly arranged separately from each other. However, if the column decoder is to be used commonly to the writing and reading, in the configuration shown in FIG. 6, a combined signal of column decoder enable signal CDE and the write instructing signal are configured to be applied to delay circuit DG3.

Column decoder enable signal CDE is inactive low level signal. In the data writing, therefore, complementary write amplifier activating signal ZWAE is at the H level until the column select operation is started, and accordingly, MOS transistors NQ12 and NQ13 shown in FIG. 5 maintain the on state. When the delay time provided by delay circuit DG3 and inverters G8 and G9 elapses after (write) column decoder enable signal CDE attained the H level, write amplifier activating signals ZWAE and WAE are made active. In the data writing, therefore, MOS transistors NQ12 and NQ13 shown in FIG. 5 turn non-conductive after the column selection, and the internal write data WDD and ZWDD are produced and written into the selected column. In a period until execution of such column selection, DQ circuit band 22 shown in FIG. 2 sends the write data via data line DBL and reference data line RDBL, to set the potential levels of signals WAN and WAN_R on nodes ND7 and ND8 to the definite state.

FIG. 7 shows an example of a configuration of a portion generating write/read instructing signal ZWZR shown in FIG. 5. Write/read instructing signal ZWZR is produced by an inverter G10 receiving write/read instructing signal WR. Write/read instructing signal WR is produced from control circuit 9 shown in FIG. 1 upon supply of a read or write command, and is activated in a selected bank based on the bank address signal. In data writing or instruction of data reading, write/read instructing signal WR is at the H level. Write/read instructing signal ZWZR generated from inverter G10 attains the L level in the data writing or data reading. In the data reading, therefore, even when data line DBL and reference data line RDBL are coupled to nodes ND7 and ND8, respectively, MOS transistors NQ14 and NQ15 are kept off, and no adverse influence is exerted on the transference of the memory cell data on data line DBL and reference data line RDBL.

MOS transistors NQ12 and NQ13 may be configured such that they are set to the off state in data reading, and have the on/off state controlled in accordance with complementary write amplifier activating signal ZWAE in the data writing. In the data reading, nodes ND7 and ND8 are isolated from data line DBL and reference data line RDBL. This reduces loads of data line DBL and reference data line RDBL in the data reading operation.

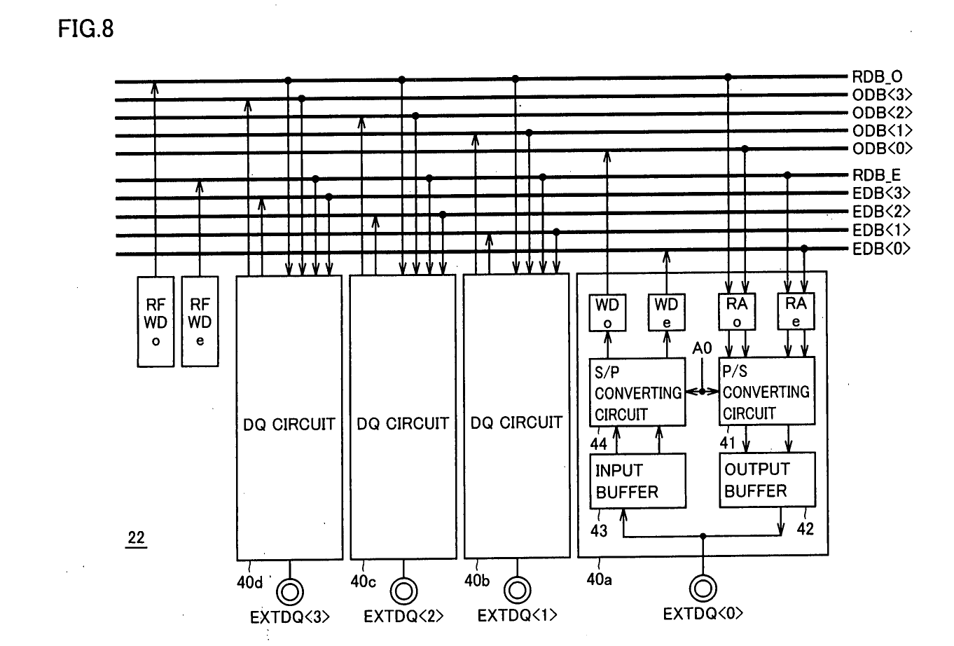

FIG. 8 schematically shows a construction of a circuit portion for four bits in DQ circuit band 22 shown in FIG. 2. In FIG. 8, DQ circuit band 22 includes DQ circuits 40a-40d sending and receiving external data EXTDQ<0>-EXTDQ<3>, respectively. These DQ circuits 40a-40d correspond to the construction including output buffer circuit 11, read data transfer circuit 12, input buffer circuit 13, write data transfer circuit 14 and Vref generating circuit 19. Since DQ circuits 40a-40d have the same construction, FIG. 8 representatively shows the construction of only DQ circuit 40a.

Corresponding to external data EXTDQ<0>-EXTDQ<3>, even-number plane data lines EDB<0>-EDB<3> and odd-number plane data lines ODB<0>-ODB<3> are arranged, respectively, and odd-number plane reference data line RDB_O and even-number plane reference data line RDB_E are also arranged.

DQ circuit 40a includes a read amplifier RAe receiving signals on reference data line RDB_E and data line EDB<0>, a read amplifier RAo receiving signals on reference data line RDB_O and data line ODB<0>, a parallel-serial converting circuit 41 receiving complementary data in parallel from read amplifiers RAe and RAo in accordance with address signal bit A0, and converts the received parallel data to serial data, and an output buffer 42 producing external data EXTDQ<0> in accordance with the complementary data received from parallel-serial converting circuit 41.

Since the 2-bit prefetch scheme is employed, read amplifiers RAe and RAo compare the data simultaneously transferred on data lines EDB<0> and ODB<<0>, with the signals on reference data lines RDB_E and RDB_O, respectively, to produce complementary data of 2 bits. Based on address signal bit A0, it is determined whether the data is to be read first from the even-number plane or the odd-number plane, and the parallel-serial converting circuit 41 determines the order of the output data of read amplifiers RAe and RAo, and successively outputs the data via output buffer 42. Internal clock signals CLK_PF and CLK_NF shown in FIG. 1 are used as the clock signal in the converting operation of parallel-serial converting circuit 41. FIG. 8 shows only arrangement of the data lines and reference data lines, and does not show paths of the clock signals.

DQ circuit 40a further includes an input buffer 43 producing complementary internal data from external data bit EXTDQ<0>, a S/P converting circuit 44 converting serial data received from input buffer 43 into parallel data, and write drivers WDe and WDo receiving data from S/P converting circuit 44, to transfer the internal data to even-number plane data line EDB<0> and odd-number plane data line ODB<0> in accordance with the received data, respectively.

S/P converting circuit 44 produces the parallel data by determining a correspondence relation between the data applied from input buffer 43 and the even- and odd-number planes in accordance with address signal bit A0.

Write drivers WDe and WDo drive data lines EDB<0> and ODB<0> of the single-end structure in accordance with the data received from S/P converting circuit 44.

In DQ circuits 40a-40d, FIG. 8 does not show the data latch shown in FIG. 1 as a circuit component. However, parallel-serial and S/P converting circuits 41 and 44 includes latch circuits for storing data to be transferred with the even- and odd-number planes.

In DQ circuit band 22, a write reference driver RFWDe driving even-number reference data line RDB_E in the data writing and a write reference driver RFWDo driving odd-number reference data line RDB_O in the data write operation are arranged corresponding to DQ circuits 40a-40d of four bits.

In data writing, when DQ circuits 40a-40d produce the internal write data, to drive data lines EDB<0>-EDB<3> and ODB<0>-ODB<3>, write reference drivers RFWDe and RFWDo arranged in the neighborhood drive reference data lines RDB_E and RDB_O, so that the reference data and the write data can arrive at a selected bank at substantially the same timing, and a sufficient margin can be ensured in the data writing.

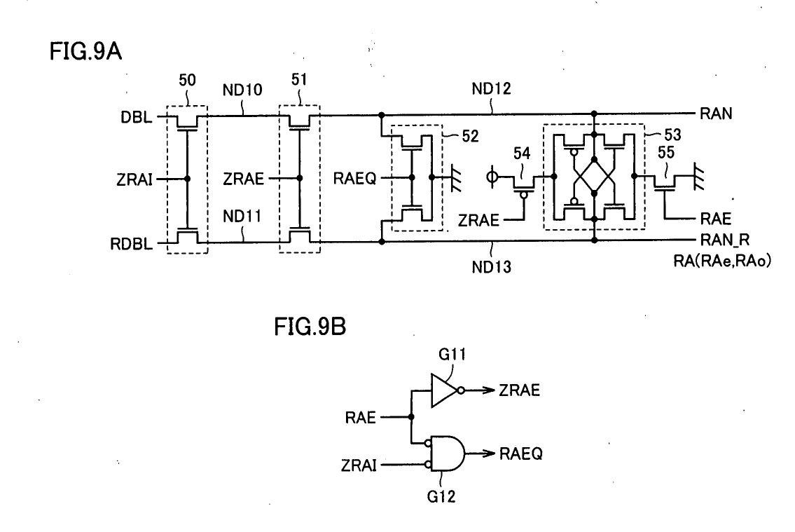

FIG. 9A shows an example of the configuration of read amplifiers RAe and RAo shown in FIG. 8. Since read amplifiers RAe and RAo differ from each other only in the associated data line and the associated data line, and have the same internal structure. Therefore, read amplifiers RAe and RAo are generically represented as read amplifiers RA in FIG. 9A.

In FIG. 9A, read amplifier RA includes a read amplifier isolating gate 50 for connecting nodes ND10 and ND11 respectively to data line DBL and reference data line RDBL in accordance with a read amplifier isolation instructing signal ZRAI, a charge confining gate 51 made conductive to couple nodes ND10 and ND11 to nodes ND12 and ND13, respectively, when a read amplifier activating signal ZRAE is inactive, a precharge circuit 52 for precharging nodes ND12 and ND13 to the ground voltage level when read amplifier equalization instructing signal RAEQ is active, a cross-coupled type amplifier 53 for differentially amplifying the signals on nodes ND12 and ND13 to produce signals RAN and ZRAN, respectively, when made active, a P-channel MOS transistor (activating transistor) 54 supplying the power supply voltage to cross-coupled type amplifier 53 when read amplifier activating signal ZRAE is active, and an N-channel MOS transistor (activating transistor) 55 made conductive to supply the ground voltage to cross-coupled type amplifier 53 when a read amplifier activating signal RAE is active.

In the data read mode, read amplifier isolation instructing signal ZRAI is at the H-level, and data line DBL and reference data line RDBL are coupled to charge confining gate 51. When cross-coupled type amplifier 53 is made active, charge confining gate 51 is turned off to isolate internal nodes of read amplifier RA from data lines DBL and RDBL. With the charges being confined, the potentials of nodes ND12 and ND13 are amplified rapidly to produce read data RAN and ZRAN.

In modes other than the data read mode, read amplifier isolating gate 50 is non-conductive, to isolate charge confining gate 51 from data line DBL and reference data line RDBL. In this state, charge confining gate 51 is conductive, and precharge circuit 52 is active, so that internal nodes ND10-ND13 in read amplifier RA are precharged to the ground voltage level.

By utilizing the isolating gate 50, the loads of data line DBL and reference data line RDBL are reduced in the data writing. Further, in the data reading, the use of charge confining gate 51 allows the generation of the signals RAN and RAN_R at the CMOS levels in accordance with small-amplitude signals on internal nodes ND10-ND13.

FIG. 9B shows an example of a configuration of a portion for generating various control signals shown in FIG. 9A. In FIG. 9B, an inverter G11 receiving read amplifier activating signal RAE produces read amplifier activating signal ZRAE. An NOR gate G12 receiving read amplifier activating signal RAE and read amplifier isolation instructing signal ZRAI produces read amplifier equalization instructing signal RAEQ. Read amplifier activating signal RAE is activated at a predetermined timing after activation of transfer control signal ZRDT shown in FIG. 4A. Read amplifier isolation instructing signal ZRAI attains the H level in accordance with the data read instructing signal in the data reading. The control signal generating portion shown in FIG. 9B is included in control circuit 9 shown in FIG. 1.

An operation of the read amplifier shown in FIG. 9A will now be described briefly. In the data writing and the precharged state, read amplifier isolation instructing signal ZRAI is at the L level, and read amplifier isolating gate 50 is non-conductive to isolate nodes ND10 and ND11 from data lines DBL and RDBL. Therefore, even when the data writing is performed in this state, read amplifier RA does not exert any influence on the write operation.

Since read amplifier isolation instructing signal ZRAI is at the L level, and read amplifier activating signal RAE is also at the L level, read amplifier equalization instructing signal RAEQ generated from NOR gate G12 shown in FIG. 9B is at the H level, and responsively precharge circuit 52 is made active to precharge nodes ND12 and ND13 to the ground voltage level. In this state, read amplifier activating signal ZRAE is at the H level, and charge confining gate 51 is conductive, and precharge circuit 52 precharges nodes ND10 and ND11 to the ground voltage level. Also, activating transistors 54 and 55 are non-conductive, and cross-coupled type amplifier 53 is inactive.

When the data read cycle starts, read amplifier isolation instructing signal ZRAI attains the H level, and nodes ND10 and ND11 are coupled to data line DBL and reference data line RDBL. When read amplifier isolation instructing signal ZRAI attain the H level, read amplifier equalization instructing signal RAEQ generated from NOR gate G12 shown in FIG. 9B attains the L level to deactivate precharge circuit 52, and accordingly, the operation of precharging nodes ND10-ND13 is completed.

When transfer control signal ZRDT shown in FIGS. 4A and 4B turns active, read data is transferred onto data line DBL and reference data line RDBL so that the potentials of nodes ND12 and ND13 change in accordance with the transferred data, and read amplifier activating signal ZRAE becomes active for a predetermined period. Responsively, charge confining gate 51 turns inactive, and cross-coupled type amplifier 53 is supplied with the power supply voltage and the ground voltage from MOS transistors 54 and 55, and differentially amplifies the data signals on nodes-ND12 and ND13.

Node ND12 receives the memory cell data via data line DBL, and node ND13 receives reference data (reference potential) via reference data line RDBL. Therefore, by differentially amplifying the potentials of nodes ND12 and ND13 by cross-coupled type amplifier 53, it is possible to amplify the memory cell data while using the potential on node ND13 as the reference potential, to produce the signals RAN and RAN_R at the CMOS levels corresponding to the memory cell data.

By arranging read amplifier RA shown in FIG. 9A in the DQ circuit, signals RAN and RAN_R at the CMOS levels can be produced from the memory cell data transferred via data line DBL of the single-end structure based on the reference potential transferred via reference data line RDBL (RDB_O or RDB_E).

Effectively, the above structure is equivalent to a structure of transferring complementary signals via data line DBL and reference data line RDBL. By differentially amplifying the equivalently complementary signals, it is possible to amplify stably the small amplitude signal of the data transferred from the internal read/write circuit in the selected bank, to produce stably the read data.

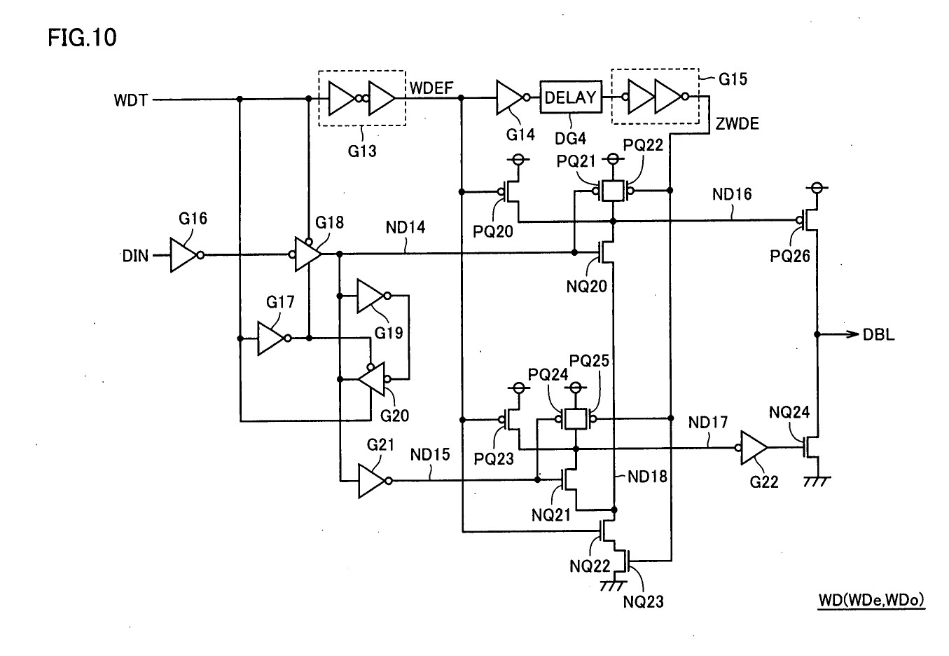

FIG. 10 shows an example of a structure of write driver WDe or WDo shown in FIG. 9. Since write drivers WDe and WDo have the same structure, write driver WDo and WDe are each generically shown as write driver WD in FIG. 10.

In FIG. 10, write driver WD includes an inverter G16 receiving data DIN from the corresponding register in the S/P converting circuit (serial-parallel converting circuit), an inverter G17 receiving a write data transfer timing signal WDT, a tristate inverter G18 selectively transmitting an output signal of inverter G16 in accordance with an output signal of inverter G17 and write data timing signal WDT, an inverter G19 receiving a signal on a node ND14 applied from inverter G18, and a tristate inverter G20 entering an output high-impedance state complementarily to tristate inverter G18 in accordance with the output signal of inverter G17 and write data transfer timing signal WDT, and transmitting an output signal of inverter G19 to node ND14.

The S/P converting circuit includes register circuits (latch circuits) for the even- and odd-number planes, respectively, and each register circuit transmits data DIN to corresponding write driver WDe or WDo. Tristate inverter G18 enters an output high-impedance state when write data transfer timing signal WDT is made active. Tristate inverter G20 operates as an inverter when made active, so that tristate inverter G20 and inverter G19 form a latch circuit to latch a signal on node ND14.

Write driver WD further includes a buffer circuit G13 receiving write data transfer timing signal WDT, an inverter G14 receiving output signal WDEF of buffer circuit G13, a delay circuit DG4 delaying the output signal of inverter G14 by a predetermined time, and a buffer circuit G15 receiving an output signal of delay circuit DG4 and producing a write driver enable signal ZWDE. Each of buffers circuits G13 and G15 is formed of an even number of inverters, and has a large driving capability to drive a gate of the corresponding MOS transistor fast.

Write driver WD further includes a P-channel MOS transistor PQ20 made conductive to precharge a node ND16 to the power supply voltage level when output signal WDEF of buffer circuit G13 is inactive, a P-channel MOS transistor PQ21 made conductive to transmit the power supply voltage to node ND16 when the signal on node ND14 is at the L-level, a P-channel MOS transistor PQ22 made conductive to transmit the power supply voltage to node ND16 when output signal ZWDE of buffer circuit G15 is active, a P-channel MOS transistor PQ23 made conductive to transmit the power supply voltage to a node ND17 when output signal WDEF of buffer circuit G13 is inactive, a P-channel MOS transistor PQ24 transmitting the power supply voltage to node ND17 when an output signal of an inverter G21 receiving the signal on node ND14 is at the L level, a P-channel MOS transistor PQ25 made conductive to supply the power supply voltage to node ND17 when write driver enable signal ZWDE provided from buffer circuit G15 is active, an N-channel MOS transistor NQ20 connected between nodes ND16 and ND18, and having a gate connected to a node ND20, an N-channel MOS transistor NQ21 connected between nodes ND17 and ND18, and having a gate connected to a node ND15, and N-channel MOS transistors NQ22 and NQ23 connected in series between node ND18 and the ground node.

MOS transistors PQ20 and PQ23 precharge the nodes ND16 and ND17 to the power supply voltage levels, respectively. Then, the voltage levels of nodes ND16 and ND17 are changed in accordance with the write data transferred onto nodes ND14 and ND15. Then, write driver enable signal ZWDE turns on MOS transistors PQ22 and PQ25, and turns off MOS transistor MQ23 so that nodes ND16 and ND17 return to the power supply voltage level.

Write driver WD further includes a P-channel MOS transistor PQ26 connected between the power supply node and data line DBL and having a gate connected to node ND16, an inverter G22 receiving a signal on node ND17, and an N-channel MOS transistor NQ24 connected between data line DBL and the ground node and having a gate receiving an output signal of inverter G22. Data line DBL is precharged to the ground voltage level.

The voltage levels of nodes ND16 and ND17 change in accordance with the write data only during a predetermined period determined by delay circuit DG4. Write driver WD is configured to drive data line DBL only during this predetermined period, and thus increase in amplitude of data line DBL can be suppressed to transmit the small amplitude signal. When the predetermined period of time elapses, write driver enable signal ZWDE attains the L level, and write driver WD enters an output high-impedance state. When the data write cycle is completed, the signal WDEF attains the L level, and write driver WD maintains the output high-impedance state.

For example, in the state where write data DIN is at the H-level, tristate inverter G18 generates L-level data onto node ND14, and inverter G21 generates H-level data onto node ND15 when write data transfer timing signal WDT is at the L level. At the rising and falling edges of the clock signal, the write data is transferred. When the data of 2 bits is written, write data transfer timing signal WDT is driven to the H level at the predetermined timing, and tristate inverter G18 enters an output high-impedance state, so that data DIN applied from the corresponding register in the S/P converting circuit is latched in write driver WD by inverter G19 and tristate inverter G20.

When output signal WDEF of buffer circuit G13 attains the H level, MOS transistors PQ20 and PQ23 are turned off to stop precharging of nodes ND16 and ND17 to the power supply voltage level. Write driver enable signal ZWDE is still at the H level, and accordingly, MOS transistor NQ23 is in an off state. Control signal WDEF applied from buffer circuit G13 is at the H-level, and MOS transistor NQ22 is conductive, so that a current path is formed from node ND18 to the ground node, and nodes ND16 and ND17 can be driven in accordance with the data latched at nodes ND14 and ND15.

Since the complementary data are latched nodes ND14 and ND15, one of nodes ND16 and ND17 is driven from the power supply voltage level to the ground voltage level, and the other node maintains the precharged power supply voltage level. When write data DIN is at the L level, node ND14 latches the L level data so that MOS transistor NQ20 is turned off, and MOS transistor NQ21 is turned on. Responsively, node ND16 is kept at the precharged voltage level, and node ND17 is driven to the ground voltage level. Accordingly, MOS transistor PQ26 is non-conductive, and MOS transistor NQ24 is turned on so that data line DBL is kept at the precharged ground voltage level.

Conversely, when write data DIN is at the H level, the H-level data is latched at node ND14. Therefore, MOS transistor NQ20 is turned on to discharge node ND16 to the ground voltage level, and responsively, MOS transistor PQ26 is turned on to raise the voltage level of data line DBL. In this state, node ND17 is at the L level, and MOS transistor NQ21 is in an off state, so that node ND17 is kept at the precharged voltage level. Therefore, MOS transistor NQ24 is kept in the off state in accordance with the output signal of inverter G22.

When a predetermined time elapses after driving of data line DBL, write driver enable signal ZWDE applied from buffer circuit G15 attains the L level so that MOS transistor NQ23 is turned off to cut off a discharging path from node ND18 to the ground node. MOS transistors PQ22 and PQ25 are turned on to drive nodes ND16 and ND17 to the power supply voltage level, respectively. Responsively, MOS transistors PQ26 and NQ24 are turned off to stop rising of the potential of data line DBL. Thereafter, the write amplifier in a selected bank amplifies the data at the predetermined timing, to produce the internal write data.

After the write data transfer is completed, write data transfer timing signal WDT attains the L level, and responsively control signal WDEF applied from buffer circuit G13 attains the L level, so that MOS transistors PQ20 and PQ23 are turned on to precharge nodes ND16 and ND17 to the power supply voltage level, respectively, and write driver WD is kept in the output high-impedance state. A precharge circuit (not shown) precharges data line DBL to the ground voltage level. Tristate inverter G18 is made active, and drives node ND14 in accordance with the output signal of inverter G16, and tristate inverter G20 enters the output high-impedance state.

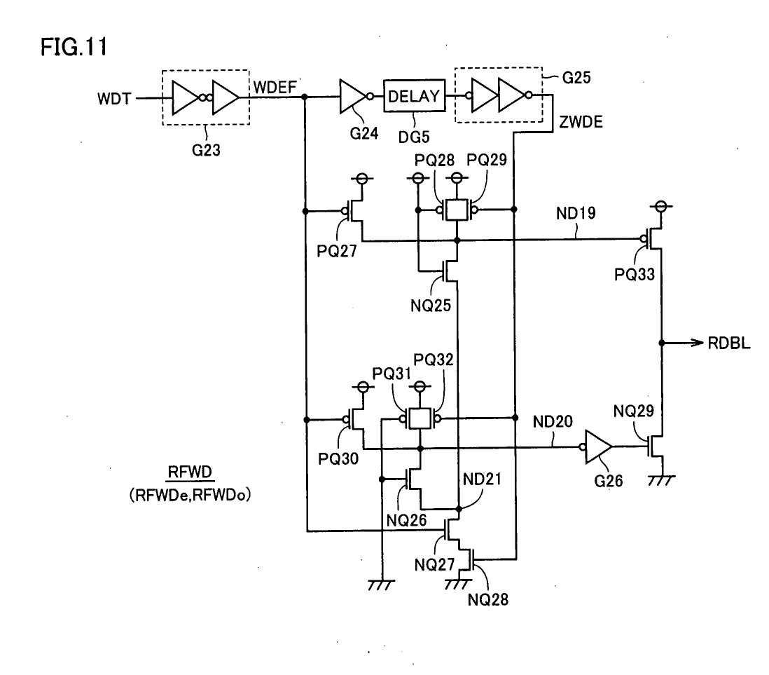

FIG. 11 shows an example of a configuration of write reference drivers RFWDe and RFWDo shown in FIG. 8. Since write reference drivers RFWDe and RFWDo have the same structure, FIG. 11 shows one of the write reference drivers as write reference driver RFWD.

In FIG. 11, write reference driver RFWD includes a buffer circuit G23 receiving write data transfer timing signal WDT, an inverter G24 receiving output signal WDEF of buffer circuit G23, a delay circuit DG5 delaying an output signal of inverter G24, a buffer circuit G25 receiving an output signal of delay circuit DG5, to produce write driver enable signal ZWDE, a P-channel MOS transistor PQ27 precharging a node ND19 when output signal WDEF of buffer circuit G23 is at the L level, a P-channel MOS transistor PQ28 connected between the power supply node and node ND19 and having a gate connected to the power supply node, a P-channel MOS transistor PQ29 connected between the power supply node and node ND19 and having a gate receiving write driver enable signal ZWDE applied from buffer circuit G25, and an N-channel MOS transistor NQ25 connected between nodes ND19 and ND21 and having a gate connected to the power supply node.

Connection of gates of MOS transistors PQ28 and NQ25 to the power supply node simulates a state, in which H-level data is transmitted to node ND14 of write data driver WD shown in FIG. 10.

Write reference driver RFWD further includes a P-channel MOS transistor PQ30 precharging node ND20 to the power supply voltage level in accordance with output signal WDEF of buffer circuit G23, a P-channel MOS transistor PQ31 connected between the power supply node and node ND20 and having a gate connected to the ground node, an N-channel MOS transistor NQ26 connected between nodes ND20 and ND21 and having a gate connected to the ground node, a P-channel MOS transistor PQ32 connected between the power supply node and node ND20 and having a gate receiving write driver enable signal ZWDE, and N-channel MOS transistors NQ23 and NQ28 connected in series between node ND21 and the ground node.

MOS transistor NQ27 receives output signal WDEF of buffer circuit G23 on its gate, and MOS transistor NQ28 receives, on its gate, write driver enable signal ZWDF from buffer circuit G25.

Gates of MOS transistors PQ31 and NQ26 are connected to the ground node. Thus, such a state is effectively achieved that the L-level data is transferred to node ND15 in write data driver WD shown in FIG. 10, or the H-level data is transmitted as write data DIN.

Write reference driver RFWD further includes an inverter G26 receiving the signal on node ND20, a P-channel MOS transistor PQ33 supplying a current from the power supply node to reference data line RDBL in accordance with the signal on node ND19, and an N-channel MOS transistor NQ29 coupling reference data line RDBL to the ground node in accordance with an output signal of inverter G26.

In the write data transferring operation, both MOS transistors PQ27 and PQ30 are in an off state, and both MOS transistors NQ27 and NQ28 are in an on state. Therefore, MOS transistor NQ25 discharges node ND19 down to the ground voltage level. Node ND20 is kept at the precharged voltage level. Responsively, MOS transistor PQ33 is turned on, and MOS transistor NQ29 is kept off, so that a current is supplied to reference data line RDBL to raise its voltage level. When a predetermined period elapses, MOS transistors PQ29 and PQ32 are turned on, and MOS transistor NQ28 is turned off in accordance with write driver enable signal ZWDE. Responsively, MOS transistor PQ33 is turned off to stop supply of the current to reference data line RDBL.

In the case where the loads of reference data line RDBL and data line DBL are equal to each other, MOS transistor PQ33 may be configured to have the current driving power smaller than that of drive transistor PQ26 of the write data driver shown in FIG. 10. According to such configuration, the potential rising rate of reference data line RDBL can be made lower than that of data line DBL, and the reference potential of reference data line RDBL can be set to the intermediate voltage level for determining the high and low levels of the write data.

Reference data line RDBL is connected to more loads than data line DBL because read amplifiers in the column-repetition band of each bank are connected thereto. Therefore, even when MOS transistors PQ33 and PQ26 have the same current driving powers, the potential rising rate of reference data line RDBL can be made slow because the load of reference data line RDBL is greater than the load of data line DBL. Therefore, the potential of reference data line RDBL can be set to the potential level intermediate between the high and low levels of the small amplitude data. Accordingly, it is only needed to determine the current driving power of drive transistor PQ33 appropriately in accordance with a relationship between loads of reference data line RDBL and data line DBL.

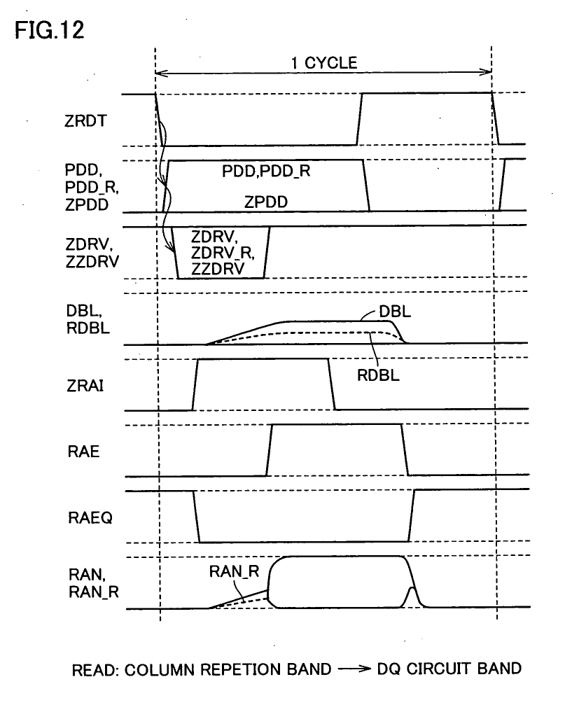

FIG. 12 is a signal waveform diagram illustrating an operation of transferring data from the column-repetition band to the DQ circuit band in the data read operation according to the first embodiment of the invention. Referring to FIG. 12, brief description will now be given on the transfer of data from the read data drivers RD included in unit read/write circuits 25a-25d shown in FIG. 3 to read data amplifiers RA (RAe and RAo) included in the DQ circuit band.

In the data read operation, when the output data of preamplifier PA shown in FIG. 3 is definite, read data transfer timing signal ZRDT changes from the H level to the L level, and responsively, the voltages of internal signals PDD and ZPDD in read data driver RD shown in FIG. 4A attain the power supply voltage level and the ground voltage level in accordance with the read data, respectively. In read reference driver RFRD shown in FIG. 4B, internal signal PDD_R attains the H level.

When the voltage levels of signals PDD, ZPDD and PDD_R change, output signals ZDRV and ZZDRV lower in a pulse form to the L level in one-shot pulse generating stage 32 of the read data driver shown in FIG. 4A, and output signal ZDRV_R is driven to and kept at the L level for a predetermined period in one-shot pulse generating stage 37 of read reference driver RFRD shown in FIG. 4B.

Responsively, the voltage level of data line DBL is set in accordance with the memory cell data, and the voltage level of reference data line RDBL rises. The potential of reference data line RDBL rises more slowly than the potential of data line DBL transmitting the H-level data. When the potentials of data line DBL and reference data line RDBL are driven, read amplifier isolation instructing signal ZRAI shown in FIG. 9A changes from the L level to the H level, and read amplifier isolating gate 50 turns conductive to couple data line DBL and reference data line RDBL to nodes ND12 and ND13 of read data amplifier RA shown in FIG. 9A, respectively. When isolating gate 50 is non-conductive, read amplifier equalization instructing signal RAEQ is similarly at the L level, and the operation of precharging nodes ND12 and ND13 by precharge circuit 52 is already completed. Therefore, the voltage levels of nodes ND12 and ND13 of the read data amplifier shown in FIG. 9A change in accordance with the signals transmitted via data line DBL and reference data line RDBL.

When a sufficient voltage difference is developed between nodes ND12 and ND13 in read data amplifier RA, read data amplifier activating signal RAE is made active at a predetermined timing, and the cross-coupled type amplifier differentially amplifies signals RAN and RAN_R on nodes ND12 and ND13, and drives the nodes ND12 and ND13 to the power supply voltage and the ground voltage level in accordance with the read data. Then, signals RAN and RAN_R are transferred to the parallel-serial (P/S) converting circuit in the next stage.

When read amplifier activating signal RAE is active in read data amplifier RA, a sufficient potential difference is developed between signals RAN and RAN_R on nodes ND12 and ND13 in the read data amplifier shown in FIG. 9A. Therefore, cross-coupled type amplifier 53 can reliably perform the amplifying operation to produce the internal read data.

When the data reading is completed, one-shot pulse generating stages 32 and 37 shown in FIGS. 4A and 4B stop the operation of generating the one-shot pulse, and read data driver RD and read reference driver RFRD enter the output high-impedance state. In addition, read amplifier isolation instructing signal ZRAI shown in FIG. 9A attains the L level, and the internal nodes of read amplifier RA are isolated from data line DBL and reference data line RDBL.

Thereafter, transfer control signal ZRDT rises to the H level in the column-repetition band so that read data driver RD and reference data driver RFRD shown in FIGS. 4A and 4B return to the precharge state, and precharge the signals PDD, ZPDD and PDD_R on the internal nodes to the ground voltage level.

Read amplifier activating signal RAE is rendered inactive, and responsively, read data amplifier RA shown in FIG. 9A is made inactive. In addition, read amplifier equalization instructing signal RAEQ is made active so that internal nodes ND12 and ND13 are equalized to the ground voltage level, and signals RAN and RAN_R attain the ground voltage level. Further, data bus equalizer 18 shown in FIG. 1 precharges data line DBL and reference data line RDBL to the ground voltage level.

In the data read operation, as described above, the column-repetition band transfers the data to the DQ circuit band via the data bus of the single-end structure, and also transfers the reference potential thereto via the reference data bus. If a potential difference that is detectable by the cross-coupled type amplifier, is present when read amplifier RA is made active in the DQ circuit band, the memory cell data can be reliably amplified.

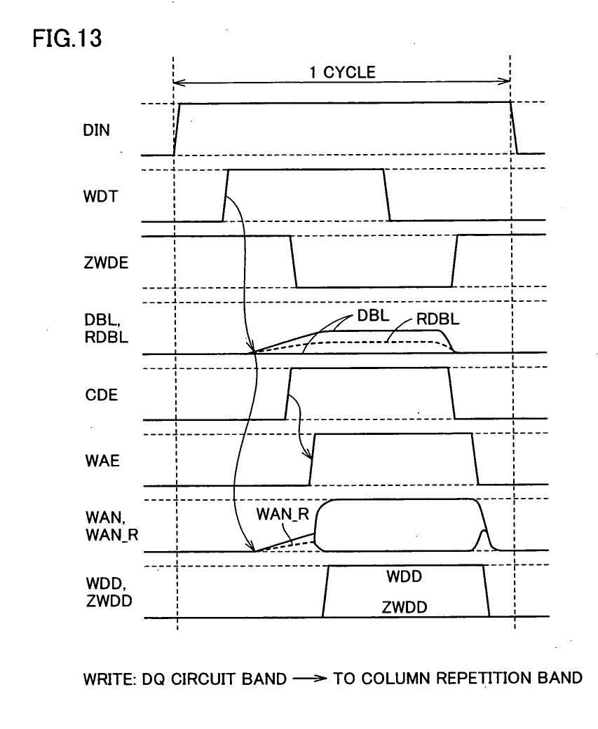

FIG. 13 illustrates signal waveforms in the case when the DQ circuit band transfers the data to the column-repetition band in the data write operation according to the first embodiment of the invention. Referring to FIG. 13, description will now be given on the operation of transferring the data from the DQ circuit band to the column-repetition band in the selected bank.

In the data write operation, input data DIN is applied from S/P converting circuit 44 shown in FIG. 8. Therefore, the transfer cycle of the write data is determined by the period of time, during which output data DIN of S/P converting circuit 44 is in the definite state.

In the data write operation, precharging of bus equalizer 18 shown in FIG. 1 likewise precharges data line DBL and reference data line RDBL.

In the data write operation, write data transfer instructing signal WDT changes from the L level to the H level, and write data driver WD in FIG. 10 and write reference driver RFWD in FIG. 11 enter the latching state. In accordance with the write data transfer instructing signal WDT, write data driver WD and write reference driver RFWD produce the internal write data in accordance with input data DIN and the ground potential, and drive the data line DBL and reference data line RDBL, respectively. In this operation, the potential on reference data line RDBL rises more rapidly than the voltage on data line DBL transferring the high-level data.

When a predetermined time elapses, write driver enable signals ZWDE in write driver WD and write reference driver RFWD attain the L level, and write driver WD and write reference driver RFWD enter the output high-impedance state so that rising of the voltage levels of reference data line RDBL and data line DBL stops. In the column-repetition band of the selected bank, MOS transistors NQ12 and NQ13 maintain the on state until column decoder enable signal CDE is made active, and the charges on data line DBL and reference data line RDBL are transmitted to internal nodes ND7 and ND8 to change the voltage levels thereof, so that signals WAN and WAN_R are set to the voltage levels corresponding to the transferred data, respectively.

Then, column decoder enable signal CDE is activated and the column select operation is performed, and thereafter write amplifier activating signal WAE is activated. Responsively, in write amplifier WA shown in FIG. 5, MOS transistors NQ12 and NQ13 are turned off and cross-coupled type amplifier AMP1 is activated to differentially amplify the signals WAN and WAN_R on nodes ND7 and ND8 to produce internal write data WDD and ZWDD. Corresponding global data lines GIO and ZGIO are driven via the write data driver, and the data is written into the selected memory cell (sense amplifier).

When the data writing is completed, write data transfer instructing signal WDT falls from the H level to the L level in the DQ circuit band, and subsequently, write driver enable signal ZWDE rises to the H level in the DQ circuit band. Responsively, write driver WD and reference write driver RFWD shown in FIGS. 10 and 11 return to the precharge state, and bus equalizer 18 shown in FIG. 1 drives data line DBL and reference data line RDBL to the ground voltage level.

In the column-repetition band, the column select operation is completed, and column decoder enable signal CDE falls to the L level. Subsequently, write amplifier activating signal WE is inactivated, and write amplifier WA enters the precharge state. Responsively, signals WAN and WAN_R are driven to the ground voltage level, and accordingly, internal write data WDD and ZWDD attain the L level.

In the data write operation, the DQ circuit band transfers the write data and the reference potential according to write data transfer signal WDT in accordance with the same timing, and the write amplifier can accurately produce the potential difference of an intended magnitude in the column-repetition band.

Write and read data drivers WD and RD are merely required to drive data line DBL, and are not required to drive a complementary data line ZDBL. Thus, it is possible to eliminate an area of a circuit portion driving complementary data line ZDBL, and accordingly, the number of transistors can be reduced.

The current driving powers of drive transistors (P-channel MOS transistors) of write and read reference drivers RFWD and RFRD driving reference data line RDBL are set to appropriate levels depending on the magnitudes of the parasitic capacitances of reference data line RDBL and data line DBL. Accordingly, the potential of reference data line RDBL can be set to a level intermediate between the high- and low-level potentials of data line DBL in the operation of differentially amplifying the data.

In particular, reference data line RDBL is coupled to many read data drivers and write amplifiers, and can be associated with the parasitic capacitance greater than the interconnection capacitance of data line DBL. Therefore, even if the circuit for driving reference data line RDBL and the circuit for driving data line DBL are formed with the same circuit configuration and the same transistor sizes, the potential changing rate of reference data line RDBL can be slower than that of data line DBL, and the potential level intermediate between the high-level data and the low-level data transferred on the data line can be easily transferred via the reference data line.

Reference data line RDBL is arranged commonly to a group of a plurality of neighboring data lines DBL. Therefore, when noises occur, common mode noise is superimposed on data line DBL and reference data line RDBL so that the influence by the noise can be cancelled. Further, the data transfer distances can be substantially uniform. Therefore, skews between signals can be suppressed so that the differential amplifying operation can be performed by accurately determining the logical level of the data on the basis of the reference potential.

[First Modification]

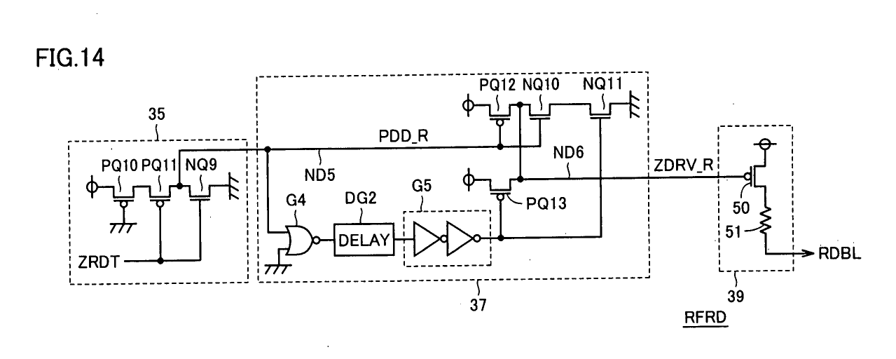

FIG. 14 shows a configuration of a first modification of the first embodiment of the invention. In the configuration shown in FIG. 14, drive stage 39 of read reference driver RFRD transferring the reference data includes a damping resistance 51 arranged between reference data line RDBL and a P-channel MOS transistor 50 receiving output signal ZDRV_R of one-shot pulse generating stage 37 on its gate. The other configuration of read reference driver RFRD is the same as that of read reference driver RFRD shown in FIG. 4B. Corresponding portions are allotted with the same reference numerals, and the description thereof is not repeated.

Damping resistance 51 has a current limiting function, and limits a rate of supply of charges from MOS transistor 50 to reference data line RDBL. Accordingly, MOS transistor 50 may have a size (current drive power) substantially equal to that of P-channel MOS transistor PQ9 of drive stage 34 (see FIG. 4A) in read data driver RD. Damping resistance 51 is formed of, e.g., a mask interconnection line, and a size thereof can be adjusted by a metal mask so that a resistance value thereof can be adjusted.

By utilizing damping resistance 51, the potential changing rate of reference data line RDBL can be reliably slower than that of data line DBL in the data read operation. Further, the resistance value thereof can be modified by the metal mask, so that the driving rate of the reference data line can be set to an optimum value depending on the load of the internal bus.

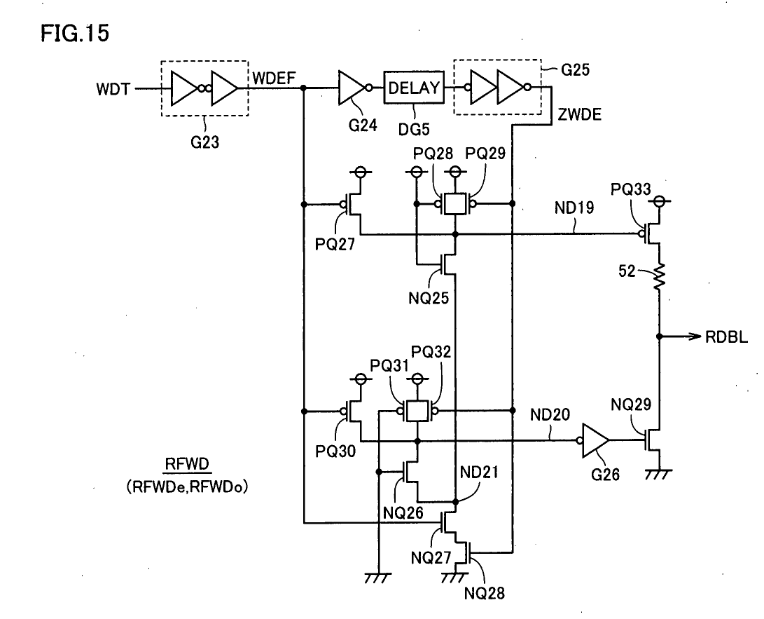

FIG. 15 shows a configuration of a write reference driver RFWD according to a modification of the first embodiment of the invention. In write reference driver RFWD shown in FIG. 15, a damping resistance 52 is connected between driving P-channel MOS transistor PQ33 and reference data line RDBL. The other configuration of write reference driver RFWD shown in FIG. 15 is the same as that of write reference driver RFWD shown in FIG. 11. Corresponding portions are allotted with the same reference numerals, and description thereof is not repeated.

By utilizing damping resistance 52, it is possible to reduce the supply rate of charges from MOS transistor PQ33 to reference data line RDBL, and accordingly, it is possible to reduce a potential change rate of reference data line RDBL in the data write operation. In this case, therefore, the current driving power (size) of MOS transistor PQ33 can be equal to that of driving P-channel MOS transistor PQ26 in write data driver WD shown in FIG. 10.

The resistance value of damping resistance 52 can likewise be adjusted with a metal mask. In the use of the metal mask, a length of polycrystalline silicon interconnection line is adjusted by the metal mask, or a length or width of a diffusion resistance is adjusted by such metal mask. Thus, the resistance value thereof is adjusted so that the reference data line driving rate can be set to an optimum value depending on to the load of the data bus.

[Second Modification]

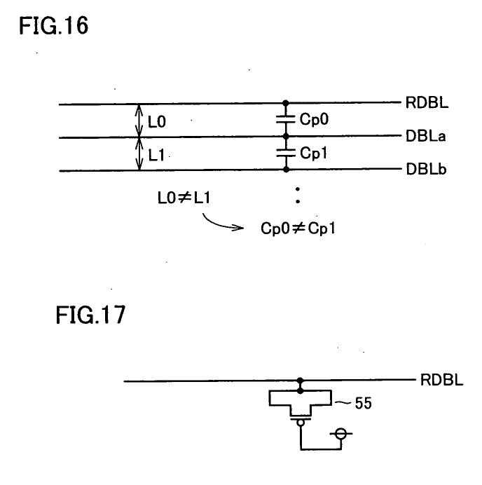

FIG. 16 shows a structure of a second modification of the semiconductor memory device according to the first embodiment of the invention. In the structure shown in FIG. 16, a pitch L1 between data lines DBLa and DBLb is different from a pitch L0 for reference data line RDBL. Therefore, an interconnection capacitance Cp0 between reference data line RDBL and adjacent data line DBL0 has a capacitance value different from that of an interconnection capacitance Cp1 between data lines DBLa and DBLb. Thus, a parasitic capacitance of reference data line RDBL is different in capacitance value from parasitic capacitances of data lines DBLa and DBLb, and the potential changing rate of reference data line RDBL can be made slower than the potential changing rates of data lines DBLa and DBLb. In particular, if the parasitic capacitance of reference data line RDBL is larger than those of data lines DBLa and DBLb, reference data line RDBL may be so arranged to have pitch L0 larger than that between data lines DBLa and DBLb, as to provide the appropriate potential level intermediate between the high and low levels of the data transmitted by data lines DBLa and DBLb.

[Third Modification]

FIG. 17 shows a structure of a third modification of the first embodiment of the invention. In the structure shown in FIG. 17, an MOS capacitor 55 is connected to reference data line RDBL. Since reference data line RDBL is precharged to the ground voltage level, MOS capacitor 55 is formed of a P-channel MOS transistor having a gate connected to the power supply node. By intentionally connecting MOS capacitor 55 to reference data line RDBL, the load capacitance value of reference data line RDBL can be set more accurately than in the case of the interconnection capacitance, and the potential changing rate can be accurately set to half the potential changing rate of the data line (DBL) so that the reference potential at the level intermediate between the high and low levels of the transfer data can be transmitted.

As described above, according to the first embodiment of the invention, the reference data line transmitting the reference data is arranged to be shared by a plurality of data lines, and a small amplitude data signal can be transferred between the column-repetition band and the DQ circuit band via the data bus of the single-end structure. Thus, it is possible to reduce the interconnection region occupied by the data bus transferring the data while enjoying the advantage of the transference of the small amplitude signal.

Since the data bus is formed into a single-end structure, it is possible to reduce the number of the driver transistors in the data line drive circuits of the column-repetition band and the DQ circuit band, and therefore a circuit occupying area can be reduced.

In the data bus, a plurality of data lines are divided into groups, and the reference data line is arranged for each predetermined number of data lines. Therefore, the reference data line is driven to transfer data and reference data for the column-repetition circuits (unit read/write circuits) in the neighboring positions. Also, the reference data line and data lines in the neighboring positions can likewise be driven in the DQ circuit band. Thus, an influence by common mode noises can be suppressed, and a skew between signals can be reduced.

### Second Embodiment

FIG. 18 schematically shows a chip layout of a semiconductor memory device according to a second embodiment of the invention. The semiconductor memory device shown in FIG. 18 differs in chip layout from the semiconductor memory device of the first embodiment shown in FIG. 2 in the following points. A Vref generating circuit 100 generating a reference voltage Vref is arranged neighboring and corresponding to a DQ circuit band 122. Reference data buses RDB_A-RDB_D are arranged corresponding to banks #A-#D, respectively. Vref generating circuit 100 includes reference potential generating circuits arranged corresponding to the respective reference data buses RDB_A-RDB_D and generating reference potential Vref when the corresponding banks are selected, and a reference potential generating circuit arranged commonly to the banks for generating the reference potential to be applied to the read data amplifiers included in DQ circuit band 122 in the data reading.

In column-repetition band 20, no circuit for generating reference potential Vref is provided. The other construction of the semiconductor memory device shown in FIG. 18 is the same as that of the semiconductor memory device shown in FIG. 2. Corresponding portions are allotted with the same reference numerals, and description thereof is not repeated.

Vref generating circuit 100 is located near and corresponding to DQ circuit band 122, and is arranged commonly to banks #A-#D concentratedly, so that it is not necessary to arrange the circuit generating the reference potential in the column-repetition band, and the layout area of the column-repetition band can be reduced. Since reference data buses RDB_A-RDB_D separately from each other are arranged corresponding to respective banks #A-#D, the loads of the reference data lines included in reference data buses RDB_A-RDB_D each can be small, and the charging/discharging currents thereof can be made small. Thus, it is possible to reduce the current consumption.

Since Vref generating circuit 100 is arranged near and corresponding to DQ circuit band 22 in a concentrate fashion, the reference potential generating circuits having the same structure can be arranged efficiently so that an area utilization efficiency can be improved.

Vref generating circuit 100 is arranged in a central region among banks #A -#D, and drives reference data buses RDB_A-RDB_D. Therefore, the changing rates of the reference data on reference data buses RDB_A-RDB_D can be made equal to each other, and thus the operating margin for writing and reading data can be improved.

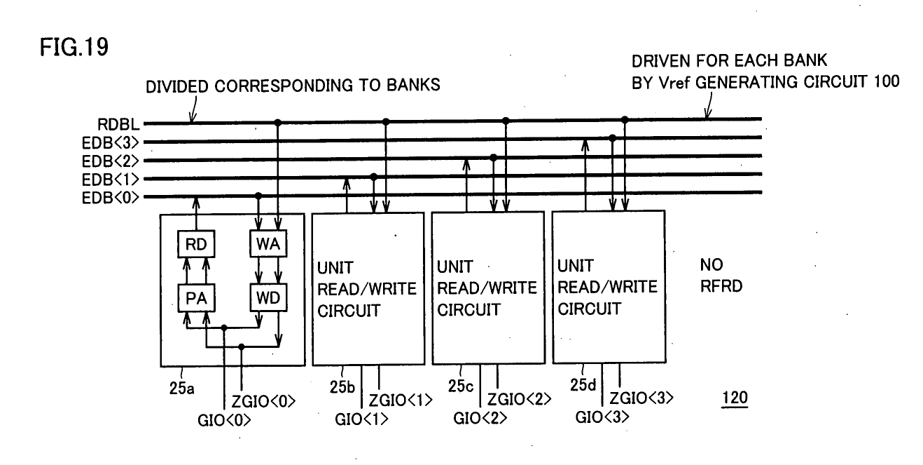

FIG. 19 schematically shows a construction of a column-repetition band 120 shown in FIG. 18. FIG. 19 shows a construction for transferring data of four bits in the column-repetition band. Similarly to the construction shown in FIG. 3, column-repetition band 120 includes unit read/write circuits 25a-25d. In column-repetition band 120, there is not provided read reference driver RFRD for generating the reference potential. Reference data line RDBL is arranged for the corresponding bank, and is driven by Vref generating circuit 100 in the data writing. Except for that reference data line RDBL is divided and arranged corresponding to the respective banks, and that read reference driver RFRD is not provided, column-repetition band 120 has the same construction as the column-repetition band shown in FIG. 3. Corresponding portions are allotted with the same reference numerals, and description thereof is not repeated.

As shown in FIG. 19, column-repetition band 120 merely includes unit read/write circuits 25a-25d, but no read reference driver RFRD for generating the reference potential. Therefore, it is possible to reduce the layout area of column-repetition band 120, and the circuits can be arranged through repetition of the same pattern, to facilitate designing of the circuit layout.

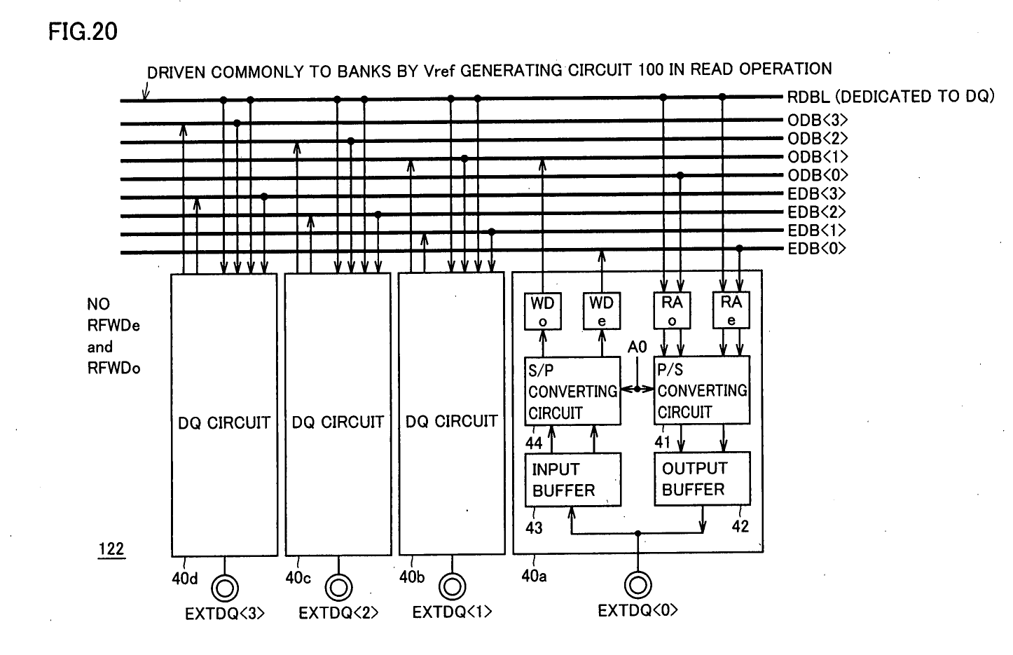

FIG. 20 schematically shows a construction of a portion of four bits in DQ circuit band 122 shown in FIG. 18. DQ circuit band 122 shown in FIG. 20 differs in construction from DQ circuit band 22 shown in FIG. 8 in the following points. Reference data line RDBL dedicated to the DQ is arranged commonly to even-number plane data lines EDB<3>-EDB<0> and odd-number plane data lines ODB<0>-ODB<3>. In each of DQ circuits 40a-40d, reference data line RDBL is coupled to read amplifiers RAe and RAo. In DQ circuit band 122, there is not provided write reference drivers RFWDe and RFWDo for generating the reference potential in the data writing.

Reference data line RDBL dedicated to DQ is driven commonly to the banks by Vref generating circuit 100 shown in FIG. 18 in the data reading. Reference data line RDBL is arranged merely in a region from Vref generating circuit 100 to DQ circuit band 122 in FIG. 18, and has a short interconnection length so that the charging/discharging current of reference data line RDBL dedicated to DQ can be small.

The other constructions of DQ circuit band 122 shown in FIG. 20 are the same as those of the DQ circuit band shown in FIG. 8. Corresponding portions are allotted with the same reference numerals, and description thereof is not repeated.

Since DQ circuit band 122 includes no reference drivers RFWDe and RFWDo for generating the reference potential in the data write operation, the circuit layout area can be small.

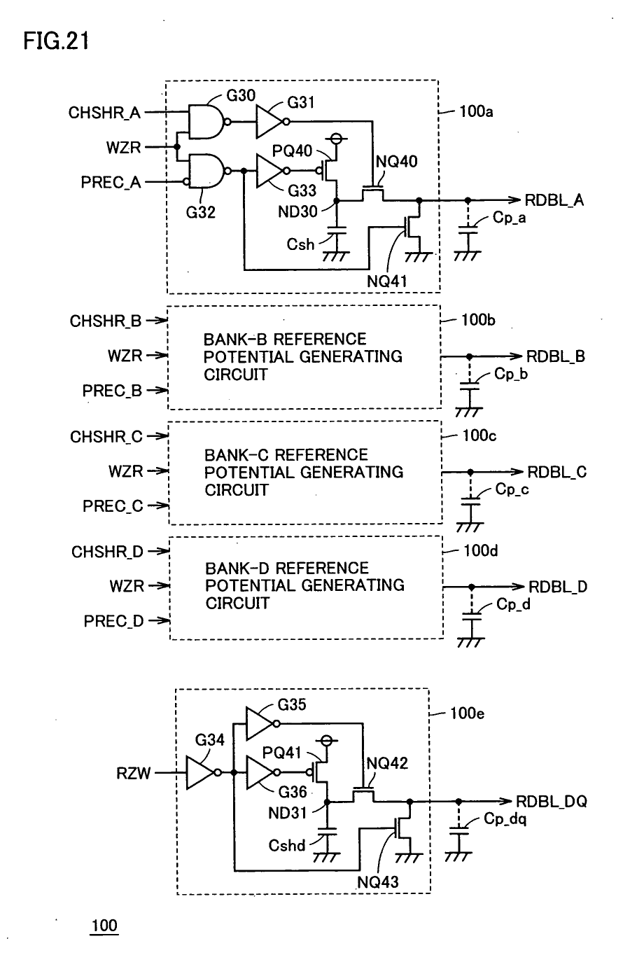

FIG. 21 shows a configuration of Vref generating circuit 100 shown in FIG. 18. In FIG. 21, Vref generating circuit 100 includes a bank-A reference potential generating circuit 100a for producing a reference potential in data writing into bank A, a bank-B reference potential generating circuit 100b for producing a reference potential in data writing into bank B, a bank-C reference potential generating circuit 100c for producing a reference potential in data writing into bank C and a bank-D reference potential generating circuit 100d for producing a reference potential in data writing into bank D.

Since reference potential generating circuits 100a-100d have the same configuration, FIG. 21 shows a specific configuration of reference potential generating circuit 100a for bank A, and merely represents the other reference potential generating circuits 100b-100d by blocks. In the configuration of reference potential generating circuits 100b-100d shown in FIG. 21, reference data lines RDBL_B-RDBL_D are arranged corresponding to banks B-D, respectively.

Bank-A reference potential generating circuit 100a includes an NAND gate G30 receiving a write mode instructing signal WZR and a reference potential generation timing signal CHSHR_A, an inverter G31 receiving an output signal of NAND gate G30, a gate circuit G32 receiving a write mode instructing signal WZR and reference data line. precharge timing signal PREC_A, an inverter G33 receiving an output signal of gate circuit G32, a P-channel MOS transistor PQ40 connected between a node ND30 and the power supply node and having a gate receiving an output signal of inverter G33, a capacitance element Csh connected between node ND30 and the ground node, an N-channel MOS transistor NQ40 made conductive to couple node ND30 to reference data line RDBL_A when an output signal of inverter G31 is at the H level, and an N-channel MOS transistor NQ41 made conductive to fix reference data line RDBL_A at the ground voltage level when the output signal of gate circuit G32 is at the H level. A parasitic capacitance Cp_a is present in reference data line RDBL_A.

Reference potential generation timing signal CHSHR_A is driven to the H-level at a predetermined timing when bank A is designated and write mode instructing signal WZR is at the H level indicating the data write period. Precharge timing signal PREC_A attains the H level when access to corresponding bank #A is completed, and attains the L level when data is to be written into bank #A in the data writing.

If a plurality of reference data lines are arranged corresponding to bank #A, capacitance Csh is arranged corresponding to each of the reference data lines.

Bank-B, bank-C and bank-D reference potential generating circuits 100b, 100c and 100d have the same configuration as bank-A reference potential generating circuit 100a. In transmission of reference potential, the reference potentials are produced by charging parasitic capacitances Cp_b-Cp_d present in corresponding reference data lines RDBL_B-RDBL_D. Bank-B to Bank-D reference potential generating circuits 100b-100d set the potentials of corresponding reference data lines RDBL_B -RDBL_D in accordance with corresponding reference potential generation timing signals CHSHR_B-CHSHR_D and precharge timing signals PREC_B-PREC_D as well as write mode instructing signal WZR. The timing signals for driving the reference data, which are applied from reference potential generating circuits 100a-100d, are produced based on the bank address signal and write mode instructing signal.

Reference potential generating circuit 100 further includes a DQ reference potential generating circuit 100e producing a reference potential for a read amplifier included in the DQ circuit band. Read amplifiers RAe and RAo (see FIG. 20) in the DQ circuit band are supplied with the reference potential via a DQ reference data line RDBL_DQ, on which a parasitic capacitance CP_dq is present.

DQ reference potential generating circuit 100e includes an inverter G34 receiving a read mode instructing signal RZW, an inverter G35 receiving an output signal of inverter G34. An inverter G36 receiving an output signal of inverter G34, a P-channel MOS transistor PQ4 transmitting the power supply voltage to a node ND3 1 when an output signal of inverter G36 is at the L level, a capacitance element Cshd connected between node ND31 and the ground node, an N-channel MOS transistor NQ42 coupling node ND31 to DQ reference data line RDBL_DQ in accordance with an output signal of inverter G35, and an N-channel MOS transistor NQ43 maintaining DQ reference data line RDBL_DQ at the ground voltage level when an output signal of inverter G34 is at the H level.

In an access cycle, read mode instructing signal RZW attains the H level when data reading is to be performed, and attains the L level when data writing is to be performed. In an access cycle, write mode instructing signal WZR attains the H level when data writing is instructed, and attains the L level when data reading is instructed.

Read data driver RD arranged in column-repetition band 120 has the same configuration as read data driver RD shown in FIG. 4A, and write amplifier WA has the same configuration as the write amplifier shown in FIG. 5.

A read amplifier arranged in DQ circuit band 122 has the same configuration as the read amplifier shown in FIG. 9A, and write data driver WD has the same configuration as that shown in FIG. 10. Description will now be given on a data transfer (read/write) operation according to the second embodiment of the invention with reference to the figures showing specific circuit configurations and others.

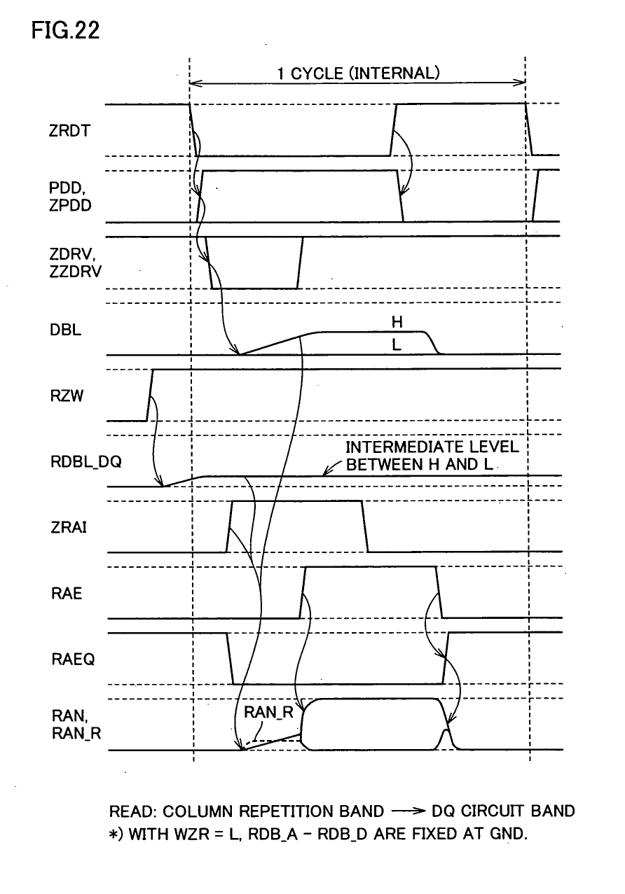

FIG. 22 illustrates signal waveforms in the case of the data read operation according to the second embodiment of the invention. In the data reading, the column-repetition band in the selected bank sends the read data to the DQ circuit band via data line DBL. Contents of the data read operation differ from those of the data read operation exhibiting the signal waveforms shown in FIG. 12. When Vref generating circuit 100 is in the precharge state, MOS transistors NQ41 and NQ43 are on, and reference data lines RDBL_A-RDBL_D and RDBL_DQ are all at the precharged level of ground voltage GND. Capacitance elements Csh and Cshd are at the precharged level of power supply voltage VDD.

When the data read cycle starts, read mode instructing signal RZW rises to the H level, and write mode instructing signal WZR is kept at the H level. Therefore, reference potential generating circuits 100a-100d maintain the precharged state, and all reference data lines RDBL_A-RDBL_D are kept at the level of ground potential GND. In DQ reference potential generating circuit 100e shown in FIG. 21, MOS transistors PQ41 and NQ43 are in an off state, and MOS transistor NQ42 is turned on in response to rising of read mode instructing signal RZW, and responsively, node ND31 is coupled to DQ reference data line RDBL_DQ. Accordingly, the charges accumulated in capacitance element Cshd are distributed to a parasitic capacitance Cp_dq, and the voltage level of DQ reference data line RDBL_DQ rises to the level depending on the capacitance values of capacitance element Cshd and parasitic capacitance Cp_dq. Thus, reference potential Vref on DQ reference data line RDBL_DQ is expressed by the following expression:

VDD·Cshd/(Cshd+Cp_dq)

By setting the capacitance of capacitance element Cshd to an appropriate value, reference potential Vref at an intended voltage level can be produced. In other words, by producing the reference potential on DQ reference data line RDBL_DQ by redistribution of charges, it is possible to set accurately the voltage level intermediate between the H- and L-level data.

Then, operations are performed similarly to those represented by the operation waveforms in FIG. 12, and data is read from read data driver RD in the column-repetition band of the selected bank, and the one-shot driving of data line DBL is effected, and the internal read data is applied to read amplifiers RA (RAe and RAo) included in DQ circuit band 122. In this data transferring operation, read amplifier equalization instructing signal RAEQ is deactivated at a predetermined timing, and responsively, precharging of internal nodes ND12 and ND13 (see FIG. 9A) of the read amplifier is completed. Then, read amplifier isolation instructing signal ZRAI attains the H level to render read amplifier isolating gate 50 (see FIG. 9) conductive, so that data line DBL and reference data line RDBL_DQ (corresponding to reference data line RDBL in FIG. 9A) are coupled to the internal nodes (nodes ND12 and ND13) of the read amplifier.

At this time point, the voltage level of DQ reference data line RDBL_DQ is already at the predetermined voltage level, and internal node ND13 (signal RN_R) of the read amplifier reaches a predetermined reference voltage level at a timing faster than the data transmitted via data line DBL. Then, signal RAN on node ND12 (see FIG. 19A) is set to the voltage level corresponding to the transferred memory cell data.

Then, read amplifier activating signal RAE is made active, and cross-coupled type amplifier performs the differential amplification to drive output signals RAN and RAN_R of the read amplifier to the signals at the CMOS levels.

Thereafter, read amplifier isolation instructing signal ZRAI falls to the L level so that the internal nodes of read amplifier RA are isolated from data line DBL and DQ reference data line DBL_DQ.

After the data is stored in the corresponding P/S converting circuit, read amplifier activating signal RAE is made inactive and read amplifier equalization instructing signal RAEQ is made active. Responsively, the internal nodes of the read amplifier is driven to the ground voltage level.

Before the differential amplifying operation of read amplifier RA, read amplifier isolation instructing signal ZRAI attains the H level, and the reference potential is transmitted to the internal node of the read amplifier. In the differential amplifying operation, as shown in FIG. 9A, even when read amplifier isolation instructing signal ZRAI is at the H level, gate circuit 51 isolates, in response to read amplifier activating signal ZRAE, the internal node of the read amplifier from reference data line RDBL_DQ. Accordingly, even when read amplifier RA performs the differential amplification to drive the internal nodes of the read amplifier to the CMOS levels, the voltage levels thereof do not affect the voltage level of reference data line RDBL_DQ.

In the case where the data reading is to be performed successively, data transfer control signal ZRDT attains the H level when one data transfer cycle ends, and responsively, internal signals PDD and ZPDD of read data driver RD (see FIG. 4A) in the column-repetition band of a selected bank are precharged to the level of ground voltage GND. Before the next transference of the read data, data line DBL is precharged to the ground voltage level. Also, the internal nodes (ND12 and ND13) in the read amplifier are precharged to the ground voltage level. If the load capacitance of DQ reference data line RDBL_DQ is sufficiently larger than the load capacitance of the internal node (ND13) of the read amplifier, even when reference data line DQBL_DQ is maintained and to be connected to the internal node of the read amplifier in the next data read out cycle, the potential change of reference data line RQBL_DQ is quite small and is maintained substantially at a constant level. Thus, the reference potential for the next data read out cycle can be generated stably.

In the data read period, when the data transfer is successively performed plural times, if reference potential Vref is generated statically through the use of the charged electric charges in the capacitance element to maintain the voltage level of reference data line RDBL_DQ at the constant level, the current consumption can be reduced as compared with the structure, in which the reference data line is charged and discharged at each cycle.

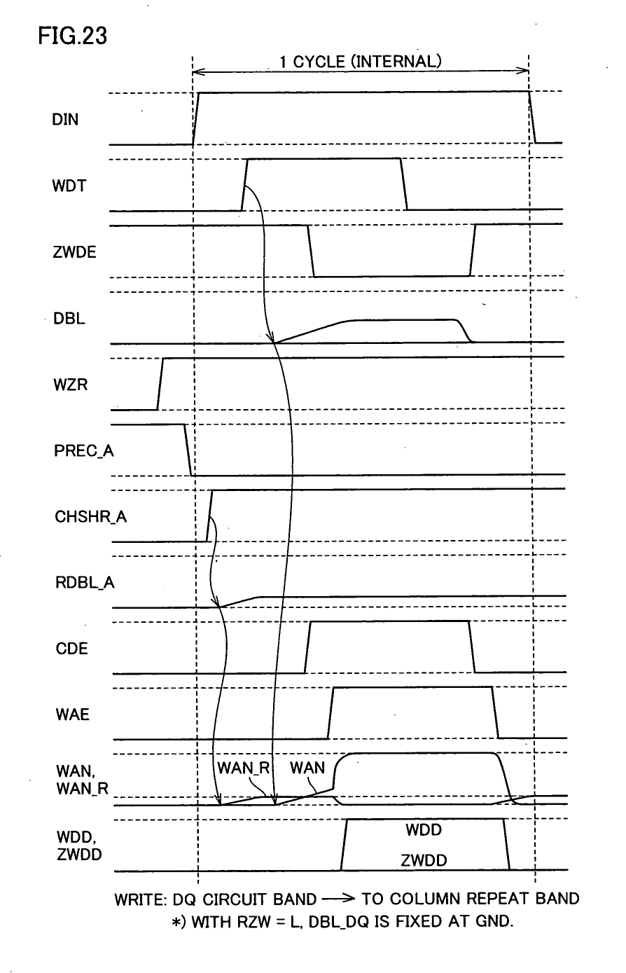

FIG. 23 is a signal waveform diagram illustrating an operation of data transfer from the DQ circuit band to the column-repetition band of the selected bank in the data writing. Referring to FIG. 23, operations for data writing will now be described. In the data write operation, write data drivers WDe and WDo in the DQ circuit band are activated to drive data line DBL in accordance with externally applied write data DIN (output data of S/P converting circuit 44). Write data drivers WDe and WDo have the same configurations as write data driver WD shown in FIG. 10, and the signal on data line DBL changes in the same manner as various control signals and data signal on data line DBL in the data write operation as already discussed with reference to FIG. 13. In Vref generating circuit 100, in the data writing, write mode instructing signal WZR are set at the H level during the write period of time, and read mode instructing signal RZW is t the L level. Responsively, MOS transistor NQ43 fixes the output voltage of DQ reference potential generating circuit 100e at the ground voltage level.

In reference potential generating circuits 100a-100d, the reference potential generating circuit for a selected bank is made active in accordance with the bank address signal, and the reference potential generating circuits corresponding to the unselected banks are maintained in the precharge state. In this case, precharge timing signal PREC_A falls to the H level in accordance with the bank address signal and the access mode instructing signal, and the output signal of gate circuit G32 shown in FIG. 21 attains the L level, and responsively, the bank-A reference potential generating circuit 100a completes the precharge operation for reference data line RDBL_A.

In other reference potential generating circuits 100b-100d, precharge timing signals PREC_B-PREC_D are continuously at the H level, and reference data lines RDBL_B-RDBL_D are kept at the level of ground voltage GND.

Then, MOS transistor PQ40 is turned off to terminate the charging operation of capacitance element Csh in bank-A reference potential generating circuit 100a.

Subsequently, reference potential generation timing signal CHSHR_A is driven to the H level based on the bank address signal and access instructing signal at a predetermined timing, and responsively, the output signal of inverter G31 attains the H level so that node ND30 is coupled to reference data line RDBL_A. Accordingly, charges accumulated in capacitance element Csh are transmitted to reference data line RDBL_A, and the charges are redistributed between a parasitic capacitance Cp_A and capacitance element Csh so that the voltage level of reference data line RDBL_A rises. Reference potential Vref of reference data line RDBL_A is expressed by the following equation:

Vref=VDD·Csh/(Csh+Cp_{—}a)

By setting the capacitance of capacitance element Csh to an appropriate value, it is possible to provide accurately the reference potential at the level intermediate between the voltages of the high-level data and the low-level data.

When the voltage level of reference data line RDBL_A rises, write amplifier WA (see FIG. 5) in the column-repetition band enters the following state. Since write amplifier activating signal WA is inactive, MOS transistors NQ12 and NQ13 shown in FIG. 5 are conductive, and charges on reference data line RDBL_A are transmitted to internal node ND8 (see FIG. 5) of the write amplifier to raise its voltage level. The parasitic capacitance of node ND8 is much smaller than the parasitic capacitance of reference data line RDBL.

Thereafter, write data drivers WDe and WDo in the DQ circuit band are activated in accordance with activation of write data transfer signal WDT, to transfer the data. Responsively, the voltage on data line DBL changes in accordance with write data DIN. The change in voltage level of data line DBL is transmitted to internal node ND7 of the write amplifier via MOS transistor NQ12 shown in FIG. 5. FIG. 23 illustrate waveforms of signals WAN and WAN_R in write amplifier WA in the case when H-level data is transmitted.

When write amplifier activating signal WAE is made active, cross-coupled type amplifier AMP1 in write amplifier WA shown in FIG. 5 becomes active to amplify differentially the signals WAN and WAN_R. In the amplifying operation of cross-coupled type amplifier AMP1, MOS transistors NQ12 and NQ13 shown in FIG. 5 are off, and data line DBL and reference data line RDBL_A are isolated from internal nodes ND7 and ND8 in write amplifier WA.

During the amplifying operation of write amplifier WA and the operation of writing data into the memory cell, write data transfer instructing signal WDT is kept inactive, and then write driver enable signal ZWD attains the H level and responsively, write data drivers WDe and WDo in the DQ circuit band turn inactive, and data line DBL is driven to the ground voltage level. Reference data line DBL_A maintains the reference potential level.

When the data writing is completed, write amplifier enable signal WAE is made inactive in accordance with deactivation of column decoder enable signal CDE, and then write mode instructing signal WZR attains the H level, and responsively, node ND7 in write amplifier WA shown in FIG. 5 is precharged to the ground voltage level. Node ND8 is configured to have the parasitic capacitance sufficiently smaller than the parasitic capacitance of reference data line RDBL_A. Accordingly, even if the node ND8 is driven to any of H level and L level by the amplifying operation of the write amplifier, the precharged voltage level of node ND8 can be restored to the voltage level corresponding to the voltage level of reference data line RDBL_A again.

In the precharging operation, the voltage level of signal WAN_R on node ND8 shown in FIG. 5 is at the voltage level intermediate between the high and low levels of the small amplitude signal. Since write amplifier activating signal WAE is inactive, both write data WDD and ZWDD can be reliably set to the L level.

In this precharging operation, internal node ND8 of write amplifier WA may be isolated from reference data line RDBL_A. Write amplifier WA may be configured similarly to read amplifier RA such that reference data line RDBL_A is coupled to internal node ND8 of write amplifier WA before activation of write amplifier WA, and reference data line RDBL_A is isolated from internal node ND8 of write amplifier WA when write amplifier WA is active. When the data transfer operation is being performed during this write period of time, bank-A reference potential generating circuit 100a maintains reference data line RDBL_A at a predetermined voltage level. Even if in the data writing, write amplifier WA equalizes the internal nodes for each data transfer, when the reference data line and the internal node of the write amplifier are isolated from each other and in addition, the parasitic capacitance on the internal node of write amplifier WA is made smaller than the parasitic capacitance of reference data line RDBL_A, discharging of electric charges on reference data line RDBL_A can be prevented to maintain the voltage level of reference data line RDBL_A at a predetermined voltage level over a long time duration of time in the data writing period.

When data is to be written into another bank B, C or D, the reference data line corresponding to the selected bank is supplied with charges from the corresponding reference potential generating circuit instead of reference data line RDBL_A, and the reference potential is produced by redistribution of charges. During the data write period, it is not necessary to perform the charging/discharging of the reference data line for each data transfer, and accordingly, the current consumption can be reduced.

Control signals CHSHR_A-CHSHR_D instruct the selected banks to produce reference potential Vref, respectively, and are generated from control circuit 9 shown in FIG. 1 in accordance with the bank address signal and the data access instructing signal (read and write commands). Precharge timing signals PREC_A-PREC_D instruct the unselected banks to precharge the reference data lines, and are generated from control circuit 9 shown in FIG. 1 in accordance with the bank address signal and the data access mode instructing signal. Write mode instructing signal WZR is set to the H level during the data write period. Control signal ZWZR is made active and inactive for each cycle of transfer of write data, and controls precharging of the internal nodes of write amplifier WA to the ground voltage level (see FIG. 5).

By executing the differential amplifying operation in the charge-confined scheme, each write amplifier can operate without an influence by the logical levels of other data bits even in the configuration in which the reference data line is arranged commonly to the data of multiple bits, and thus each write amplifier can accurately perform the differential amplifying operation based on the reference potential.

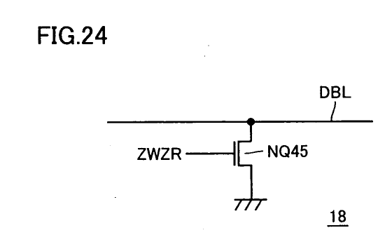

FIG. 24 shows an example of a construction of bus equalizer 18 shown in FIG. 1. FIG. 24 shows a construction of bus equalizer 18 for one data line DBL. In FIG. 24, bus equalizer 18 includes an N-channel MOS transistor NQ45 connected between the ground node and data line DBL and having a gate receiving control signal ZWZR. Control signal ZWZR attains the L level when the write or read data is to be transferred, but otherwise attains the H-level. In bus equalizer 18, data line DBL can be precharged to the ground voltage level in accordance with control signal ZWZR after each data transfer cycle.

According to the second embodiment, reference data lines RDBL are precharged to the ground voltage level by reference potential generating circuits 100a-100e, respectively.

In the construction shown in FIG. 18, the reference data lines are arranged corresponding to the respective banks. However, the reference data line may be arranged commonly to all the banks. This can reduce the number of the reference potential generating circuits, and thus can reduce the circuit occupation area.

On the both sides of the reference data line, shield interconnection lines fixed, e.g., at the power supply voltage-level or ground voltage level may be arranged for protecting the voltage level of reference potential Vref of the reference data line against noises from adjacent interconnection lines.

[Modification]

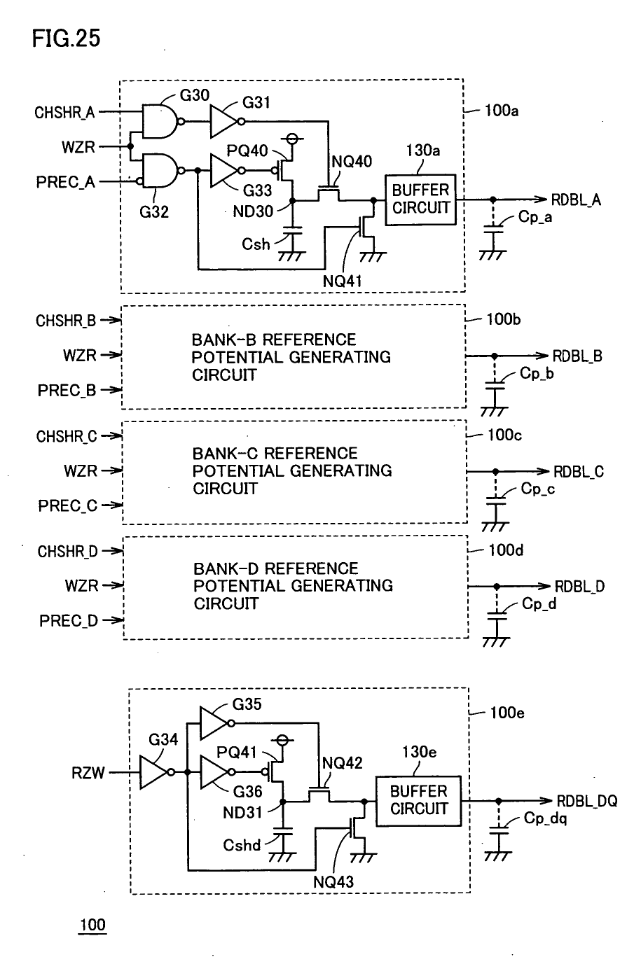

FIG. 25 schematically shows a configuration of a modification of the second embodiment of the invention. In FIG. 25, reference potential generating circuits 100a-100e in Vref generating circuit 100 are provided at output stages with buffer circuits 130a-130e, respectively. The other configuration of the Vref generating circuit shown in FIG. 25 is the same as those of Vref generating circuit shown in FIG. 21. Corresponding portions are allotted with the same reference numerals, and description thereof is not repeated.

Buffer circuits 130a-130e have the voltage follower function, and prevent the corresponding reference data lines RDBL_A-RDBL_D and RDBL_DQ from entering the output high-impedance state when charges are supplied to reference data lines RDBL_A-RDBL_D and RDBL_DQ.

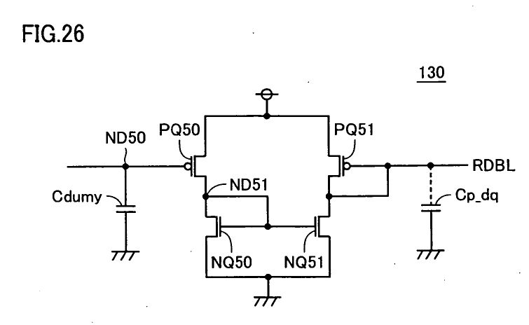

FIG. 26 shows by way of example the configuration of buffer circuits 130a-130e shown in FIG. 25. Since these buffer circuits 130a-130e have the same configuration, FIG. 26 shows buffer circuit 130 as a representative of buffer circuits 130a-130e.

In FIG. 26, buffer circuit 130 includes a P-channel MOS transistor PQ50 connected between the power supply node and a node ND51 and having a gate connected to a node ND50, a P-channel MOS transistor PQ51 connected between the power supply node and reference data line RDBL and having a gate connected to reference data line RDBL, an N-channel MOS transistor NQ50 connected between node ND51 and the ground node and having a gate connected to node ND51, and an N-channel MOS transistor NQ51 connected between reference data line RDBL and the ground node and having a gate connected to node ND51.

In band-A reference potential generating circuit 100a, node ND50 is connected to MOS transistor NQ40 in a preceding stage, and is kept at the ground voltage level by MOS transistor NQ41 when in the precharged state. In DQ reference potential generating circuit 100e, node ND50 is connected to MOS transistors NQ42 and NQ43, and is kept at the ground voltage level when in the precharged state.

Node ND50 is connected to a dummy capacitance element Cdumy, which has a capacitance value substantially equal to that of a parasitic capacitance Cp_dp present in reference data line RDBL.

In the precharged state, MOS transistors NQ41 and NQ43 shown in FIG. 25 maintains dummy capacitance element Cdumy at the ground voltage level. In this case, MOS transistor PQ50 is conductive, and supplies a current to node ND51. MOS transistors NQ50 and NQ51 form a current mirror circuit, and a current of the same magnitude as that flowing through MOS transistor NQ50 flows through MOS transistor NQ51 (when the mirror ratio is equal to unity). MOS transistor PQ51 supplies a current to MOS transistor NQ51. MOS transistor PQ51 converts the current flowing through MOS transistor PQ51 into a voltage, and transmits the converted voltage to reference data line RDBL. Therefore, reference data line RDBL in the precharged state is kept substantially at the ground voltage level, similarly to node ND50.

In transmission of the reference potential, node ND50 is coupled to corresponding capacitance element Csh or Cshd. Therefore, the charges are redistributed between capacitance element Csh or Cshd and dummy capacitance element Cdumy, and the voltage level of node ND50 rises. In accordance with the voltage level of node ND50, an amount of the current flowing through MOS transistor PQ50 lowers as compared with that in the precharged state, and responsively, the voltage level of node ND51 lowers so that an amount of the current flowing through MOS transistor NQ50 lowers. A mirror current of the current flowing through MOS transistor NQ50 flows through MOS transistor NQ51. The current flowing through MOS transistor NQ51 is supplied to MOS transistor PQ51, and is converted by MOS transistor PQ51 to a voltage. MOS transistors PQ50 and PQ51 have the equal source-gate voltages, and therefore reference data line RDBL is kept at the same voltage level as the charged voltage of dummy capacitance element Cdumy. Thus, parasitic capacitance Cp_dp is charged to the same voltage level as dummy capacitance element Cdumy.

In data transfer, therefore, reference potential Vref of reference data line RDBL is supplied with charges from buffer circuit 130, and therefore is prevented from entering an output high-impedance state to be influenced by noises. Even if the charges on reference data line RDBL is consumed through differential amplification by the cross-coupled type amplifier in each data transfer cycle in the data write period or data read period, reference data line RDBL is supplied with the charges from a voltage follower formed of MOS transistors PQ50, PQ51, NQ50 and NQ51, and the reference data line RDBL is kept at the predetermined voltage level stably. Accordingly, by arranging such buffer circuit in the output stage of the reference potential generating circuit, it is possible to prevent the reference data line from entering the output high-impedance state in data transfer, and the reference potential of high noise immunity can be transmitted to the reference data line. Further, the reference data line can be stably kept at the predetermined voltage level.

By utilizing dummy capacitance element Cdumy, reference potential Vref at the intermediate voltage level can be accurately produced.

According to the second embodiment, as described above, the circuit generating reference potential Vref is arranged corresponding to the DQ circuit band in the concentrated fashion, and supplies the reference potentials to the respective banks in a distributed fashion. Therefore, it is not necessary to arrange a circuit generating the reference potential in the column-repetition band, and a circuit occupation area can be reduced.

It is not necessary to arrange the circuit for generating the reference potential in the DQ circuit band so that the circuit layout area can be reduced.

The capacitance element is used for producing the reference voltage, so that the reference voltage at an intended voltage level can be stably produced.

According to the invention, as described above, since the data bus for transferring the internal data has the single-end structure, the number of signal lines in the data bus as well as the interconnection area can be reduced.

In particular, the circuit for generating the reference potential, which provides the criterion for determining the logical level of internal data, is arranged corresponding to the DQ circuit band in a concentrated fashion, and accordingly can be arranged efficiently.

Since the reference data lines transmitting the reference potential are arranged corresponding to the respective banks, the interconnection length of the reference data lines can be made short, so that it is possible to reduce the charging/discharging currents of the reference data lines, and accordingly, the current consumption can be reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a plurality of memory banks each having a plurality of memory cells, and being driven to a selected state independently of each other;
a data bus of a multi-bit width, arranged commonly to the memory banks, for transferring data, said data bus having a single-end structure in which one data line is provided per one bit of the data;
a plurality of reference data lines arranged corresponding to the memory banks;
input/output circuitry for receiving and externally transmitting external data;
a plurality of reference potential generating circuits arranged corresponding to said input/output circuitry in a concentrated fashion and arranged corresponding to the memory banks, for driving, in a data access, the reference data line corresponding to at least a selected bank, to produce a reference potential providing a criterion for determining high and low levels of a logical level of data; and
receiver circuitry for comparing, in said data access, each of bits on said data bus with a potential of a corresponding reference data line to produce data corresponding to a logical level of each of the bits.

2. The semiconductor memory device according to claim 1, wherein
said receiver circuitry includes write amplifiers, arranged corresponding to the respective memory banks, each activated in accordance with a data write instruction when a corresponding memory bank is selected, to compare write data applied from said input/output circuitry via said data bus with the potential of a corresponding reference data line, for producing internal write data to the corresponding memory bank.

3. The semiconductor memory device according to claim 1, wherein
said plurality of reference potential generating circuits include:
write reference potential generating circuits, arranged corresponding to the respective memory banks, each for driving a corresponding reference data line in accordance with a data write instructing signal when a corresponding memory bank is selected, and
a read reference potential generating circuit arranged commonly to said plurality of memory banks, and producing the reference potential for an output circuit in said input/output circuit in accordance with a data read instructing signal.

4. The semiconductor memory device according to claim 1, wherein said plurality of reference potential generating circuits include a plurality of write reference potential generating circuits, arranged corresponding to the respective memory banks, each being activated in response to a write instructing signal including a bank designating signal, to drive a corresponding reference data line, and
the write reference potential generating circuit in an active state transmits charged electric charges of a capacitance element to the corresponding reference data line.

5. The semiconductor memory device according to claim 4, wherein
each of said write reference potential generating circuits further includes:
a bus precharge element for precharging the corresponding reference data line to a predetermined voltage level in response to a precharge instructing signal generated for a corresponding memory bank, and
a capacitance precharge element for precharging said capacitance element to a voltage level different from said predetermined voltage level in response to said precharge instructing signal generated for the corresponding memory bank.

6. The semiconductor memory device according to claim 4, wherein
said capacitance element has a capacitance value determined depending on a capacitance value of a parasitic capacitance of the corresponding reference data line.

7. The semiconductor memory device according to claim 1, wherein
each reference potential generating circuit includes:
a capacitance element being precharged to a predetermined potential, and
a voltage follower for driving a corresponding reference data line in accordance with a charged potential of said capacitance element when said each reference potential generating circuit is active.

8. The semiconductor memory device according to claim 7, wherein
said voltage follower includes, on an input thereof, a dummy capacitance element receiving charges from the corresponding capacitance element when the corresponding memory bank is selected, and said dummy capacitance element has a same capacitance value as the corresponding reference data line.

9. The semiconductor memory device according to claim 8, wherein
each reference potential generating circuit further includes:
a precharge element for precharging said dummy capacitance element to a fixed voltage different from said predetermined potential when the corresponding bank is non-selected, and
a transfer gate for coupling said capacitance element to said dummy capacitance element in accordance with a write instruction when the corresponding memory bank is selected.

10. The semiconductor memory device according to claim 1, wherein
said plurality of reference potential generating circuits further include a read reference potential generating circuit arranged corresponding to said input/output circuitry and commonly to said plurality of memory banks, and producing a reference potential for an output circuit included in said input/output circuit in a data read operation; and
said read reference potential generating circuit includes:
a capacitance element being precharged to a predetermined potential, and
a transfer circuit for coupling said capacitance element to a read reference potential line coupled to said output circuit in response to a data read instruction.

11. The semiconductor memory device according to claim 10, wherein
said read reference potential generating circuit further includes a voltage follower for driving said read reference potential line in accordance with charges supplied from said transfer circuit.

12. The semiconductor memory device according to claim 11, wherein
said voltage follower includes, on an input thereof, a dummy capacitance element receiving charges from a corresponding capacitance element in data reading, and said dummy capacitance element has a same capacitance value as a reference data line to said output circuit.

13. The semiconductor memory device according to claim 1, wherein
said input/output circuitry includes a plurality of read amplifiers for comparing, in data read access, the bits on said data bus with a potential of a corresponding reference data line for producing internal read data, and a plurality of output circuits provided corresponding to the read amplifiers for producing said external data in accordance with the internal read data received from the read amplifiers.
